(19) United States
(12) Patent Application Publication
(10) Pub. No.: US 2026/0371814 A1
(43) Pub. Date: Nov. 19, 2026

(54) DISPLAY PANEL AND ELECTRONIC DEVICE INCLUDING THE SAME

(71) Applicant: Samsung Display Co., Ltd., Yongin-si (KR)

(72) Inventors: Minki YANG, Yongin-si (KR); Daehyun KIM, Yongin-si (KR); Mihae KIM, Yongin-si (KR); Hyunae PARK, Yongin-si (KR); Heyjin SHIN, Yongin-si (KR)

(73) Assignee: Samsung Display Co., Ltd., Yongin-si (KR)

(21) Appl. No.: 19/544,315

(22) Filed: Feb. 19, 2026

(30) Foreign Application Priority Data
May 13, 2025 (KR) 10-2025-0062188

(51) Int. Cl. H10H 29/49; H10H 29/32

(52) U.S. Cl. CPC H10H 29/49; H10H 29/32

(57) ABSTRACT

Provided is a display panel including a substrate including a display area and a peripheral area outside the display area, a first pixel and a second pixel are disposed in the display area, a first data line electrically connected to the first pixel in a first direction, a second data line electrically connected to the second pixel, a conductive line electrically connected to at least one of the first pixel and the second pixel, the conductive line configured to transfer a signal or a voltage, and a data transfer line including a horizontal connection line electrically connected to the second data line. A portion of the horizontal connection line extends in a second direction, at least one of the horizontal connection line or the conductive line includes a first connection portion and a second connection portion electrically connected to the first connection portion.

### CROSS-REFERENCE TO RELATED APPLICATION

This application is based on and claims priority under 35 U.S.C. § 119 to Korean Patent Application No. 10-2025-0062188, filed on May 13, 2025, in the Korean Intellectual Property Office, the disclosure of which is incorporated by reference herein in its entirety.

### BACKGROUND

One or more example embodiments relate to a display panel and an electronic device including the same.

Recently, the usage of display devices has diversified to a variety of different electronic products. Additionally, as display devices become more widely used, the desire for high-quality display devices has increased. Accordingly, it may be advantageous to manufacture high-resolution display devices including an increased number and/or density of electronic elements of various configurations within a narrow region.

### SUMMARY

One or more example embodiments include a display panel with improved display quality and an electronic device including the display panel. However, such objectives are just examples, and the scope of example embodiments are not limited thereto.

Additional aspects will be set forth in part in the description which follows and, in part, will be apparent from the description, or may be learned by practice of the presented embodiments of the disclosure.

According to one or more example embodiments, a display panel includes a substrate including a display area and a peripheral area outside the display area, a first pixel and a second pixel are disposed in the display area, a first data line electrically connected to the first pixel in a first direction, a second data line electrically connected to the second pixel in the first direction, a conductive line electrically connected to at least one of the first pixel and the second pixel in the first direction, the conductive line configured to transfer at least one of a signal or a voltage, and a data transfer line including a horizontal connection line electrically connected to the second data line. At least a portion of the horizontal connection line extends in a second direction, the second direction crossing the first direction, at least one of the horizontal connection line or the conductive line includes a first connection portion and a second connection portion electrically connected to the first connection portion, and the at least one of the horizontal connection line or the conductive line is on a layer at a level different from a level of the first connection portion.

According to one or more example embodiments, an electronic device includes a display panel, and a lower cover defining an exterior of the electronic device, the lower cover including an opening exposing a portion of the display panel. The display panel includes a substrate including a display area and a peripheral area outside the display area, a first pixel and a second pixel are disposed in the display area, a first data line electrically connected to the first pixel in a first direction, a second data line electrically connected to the second pixel in the first direction, a conductive line electrically connected to at least one of the first pixel and the second pixel in the first direction, the conductive line configured to transfer at least one of a signal or a voltage, and a data transfer line including a horizontal connection line electrically connected to the second data line. At least a portion of the horizontal connection line extends in a second direction, the second direction crossing the first direction, at least one of the horizontal connection line or the conductive line includes a first connection portion and a second connection portion electrically connected to the first connection portion, and the at least one of the horizontal connection line or the conductive line is on a layer at a level different from a level of the first connection portion.

Aspects, features, and advantages other than the above described things will become apparent from the following detailed description of the disclosure, the accompanying drawings, and claims.

These general and specific aspects may be implemented by using a system, a method, a computer program, or a combination of a certain system, method, and computer program.

### BRIEF DESCRIPTION OF THE DRAWINGS

The above and other aspects, features, and advantages of some example embodiments of the disclosure will be more apparent from the following description taken in conjunction with the accompanying drawings, in which:

FIG. 1 is a schematic block diagram of an electronic device according to some example embodiments;

FIG. 2 is a schematic view of the electronic device according to some example embodiments;

FIG. 3 is a schematic view showing a case where the electronic device according to some example embodiments is a wearable electronic device;

FIG. 4 is a schematic view showing a case where an electronic device according to some example embodiments is a vehicle electronic device;

FIG. 5 is a schematic plan view of a display module including a display panel according to some example embodiments;

FIG. 6 is a schematic side view of the display module and a lower cover of FIG. 5;

FIG. 7 is a schematic plan view of the display module of FIG. 5;

FIG. 8 is a schematic enlarged conceptual view of a region A of the display module of FIG. 7;

FIG. 9 is a view of a modification of FIG. 8;

FIG. 10 is an equivalent circuit diagram of a pixel disposed in a display area of a display panel included in the display module of FIG. 7;

FIG. 11 is a schematic arrangement view showing positions of transistors, capacitors and the like in pixels disposed in a display area of the display panel;

FIGS. 12 to 20 are schematic arrangement views of elements such as transistors and capacitors, for each layer, of the display panel shown in FIG. 11;

FIG. 21 is a schematic arrangement view of pixel electrodes of the display panel of FIG. 11;

FIG. 22 is a schematic cross-sectional view of the display panel taken along line B-B′ of FIGS. 11 to 21;

FIG. 23 is a schematic cross-sectional view of the display panel taken along line C-C′ of FIGS. 11 to 21;

FIGS. 24 to 25 are schematic arrangement views of elements such as transistors and a capacitor, for each layer, of a display panel according to some example embodiments; and

FIG. 26 is a schematic cross-sectional view of the display panel taken along line C-C′ of FIGS. 24 and 25.

### DETAILED DESCRIPTION

Reference will now be made in detail to some example embodiments, examples of which are illustrated in the accompanying drawings, wherein like reference numerals refer to like elements throughout. In this regard, some example embodiments may have different forms and should not be construed as being limited to the descriptions set forth herein. Accordingly, the example embodiments are merely described below, by referring to the figures, to explain aspects of the present description. As used herein, the term “and/or” includes any and all combinations of one or more of the associated listed items. Throughout the disclosure, the expression “at least one of a, b, and c” indicates only a, only b, only c, both a and b, both a and c, both b and c, all of a, b, and c, or variations thereof.

As the disclosure allows for various changes and numerous embodiments, some example embodiments will be illustrated in the drawings and described in the detailed description. Effects and features of the present example embodiments, and methods for achieving them will be clarified with reference to some example embodiments described below in detail with reference to the drawings. However, example embodiments are not limited to some example embodiments described below and may be implemented in various forms.

Hereinafter, some example embodiments will be described with reference to the accompanying drawings, wherein, like or corresponding elements are given like reference numerals when describing with reference to the drawings, and a repeated description thereof is omitted.

In some example embodiments below, such terms as first and second are not used in a limited meaning and are used for the purpose of distinguishing one element from another. In addition, the singular forms “a,” “an,” and “the” as used herein are intended to include the plural forms as well unless the context clearly indicates otherwise.

It will be understood that the terms “comprise,” “comprising,” “include” and/or “including” as used herein specify the presence of stated features or components but do not preclude the addition of one or more other features or components. It will be further understood that, when a layer, region, or component is referred to as being “on” another layer, region, or component, it can be directly or indirectly on the other layer, region, or component. That is, for example, intervening layers, regions, or components may be present.

Sizes of elements in the drawings may be exaggerated or reduced for convenience of explanation. As an example, the size and thickness of each element shown in the drawings are arbitrarily represented for convenience of description, and thus, the example embodiments are not limited thereto.

An x axis, a y axis and a z axis are not limited to three axes of the rectangular coordinate system, and may be interpreted in a broader sense including the same. For example, the x axis, y axis, and z axis may be perpendicular to one another, or may represent different directions that are not perpendicular to one another.

In the case where a certain example embodiment may be implemented differently, a specific process order may be performed in the order different from the described order. As an example, two processes successively described may be performed substantially simultaneously or may be performed in the opposite order of the described order.

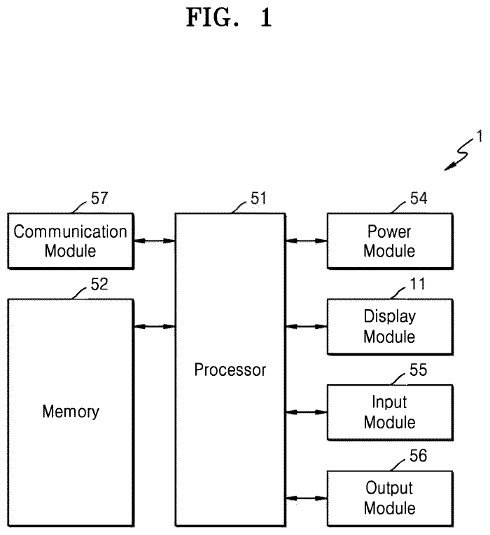

FIG. 1 is a schematic block diagram of an electronic device 1 according to some example embodiments. The electronic device 1 according to some example embodiments may be a display device. In addition to a display module 11, the electronic device may further include a module and the like having another additional function.

As shown in FIG. 1, the electronic device 1 according to some example embodiments may include the display module 11, a processor 51, memory 52, a power module 54, an input module 55, an output module 56, and a communication module 57.

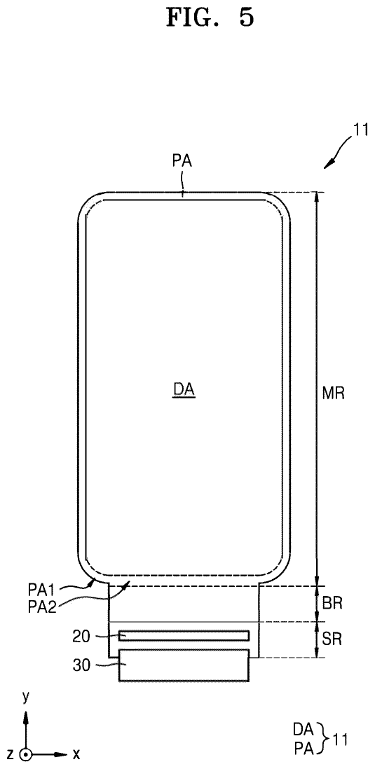

The display module 11 may include a display panel 10 (see FIG. 5) as described below. As an example, the display module 11 may include the display panel 10, a data driver 20 mounted thereon, and the like. The display panel 10 is described below.

The processor 51 may control most of elements of the electronic device 1. As an example, the processor 51 may output digital video data to the display module 11 such that the display module 11 displays images, and may receive input data from the input module 55 to allow a function corresponding to the relevant data to be performed by the electronic device 1. The processor 51 may include at least one of a central processing unit (CPU), an application processor (AP), a graphic processing unit (GPU), a communication processor (CP), an image signal processor (ISP), and a controller.

In some example embodiments, the processor 51 may be divided into two or more portions in a functional or structural viewpoint. As an example, the processor 51 may include a main processor in the form of a first driving chip including a central processing unit, and an auxiliary processor in the form of a second driving chip, which is a portion of the display module 11. The auxiliary processor in the form of the second driving chip may include a controller receiving image signals from the main processor and processing image signals to match interface specifications of the display panel 10 included in the display module 11.

The memory 52 may include at least one of a non-volatile memory and a volatile memory. The memory 52 may store data information for operations of the processor 51 or the display module 11. When the processor 51 executes an application stored in the memory 52, data signals for images and/or an input control signal may be transferred to the display module 11, and the display module 11 may process provided signals and output image information.

The power module 54 may include a power supply module such as a power adapter or a battery unit, and a power converting module converting power supplied by the power supply module and generating power for operations of the electronic device 1. Power conversion by the power converting module may include DC-DC conversion, AC-DC conversion, and DC-AC conversion. However, example embodiments are not limited thereto.

The input module 55 may provide input information to the processor 51 and/or the display module 11. The input module 55 may include not only a physical button, a keyboard, and a microphone, but also various kinds of sensor modules. Examples of the sensor module may include a touch sensor, a pressure sensor, a distance sensor, a position sensor, a digitizer, a motion recognition sensor, a camera sensor, a light reception sensor, a photoelectric conversion sensor, and/or a temperature sensor. In addition, the sensor module may include biometric sensors such as a blood pressure sensor, a blood sugar sensor, an electrocardiogram sensor, and/or a heart rate sensor.

The output module 56 may receive information other than images received from the processor 51 and may provide the information to a user. The output module 56 may include, for example, a sound module, a haptic module, and/or a light-emitting module. In addition, the output module 56 may include a unique functional module of the electronic device 1 such as a cooling module of a refrigerator.

For reference, the display module 11 may be also in charge of an output function. As an example, the display panel 10 included in the display module 11 may display (output) information processed by the electronic device 1. As an example, the display panel 10 may display execution screen information of an application driven by the electronic device 1, a user interface (UI), or graphic user interface (GUI) information corresponding to the execution screen information. The display panel 10 may include a display layer and a touchscreen layer, wherein the display layer displays images, and the touchscreen layer senses a user's touch input. Accordingly, the display panel 10 may serve as a portion of the input module 55 that provides an input interface between the electronic device 1 and a user, and simultaneously, serve as a portion of the output module 56 that provides an output interface between the electronic device 1 and a user.

The communication module 57 is a module responsible for transmission/reception of information between the electronic device 1 and an external device, and may include a receiver and a transmitter. The communication module 57 may include various kinds of wireless communication modules such as a mobile communication module, a broadcasting reception module, a wireless Internet module, a short range communication module, a Wi-Fi module, and/or a Bluetooth module, or various kinds of wired communication modules.

The electronic device 1 shown in FIG. 1 is just an example. In an example, a display device not having a communication function may not include the communication module 57. In some example embodiments, the electronic device 1 includes a display device, at least one of elements of the electronic device 1 may be included in the display device. In addition, some of individual modules functionally included in one module may be included in the display device, and other some may be included in the electronic device 1 separately from the display device. As an example, the display device may include the display module 11, and the processor 51, the memory 52, and the power module 54 may be elements of the electronic device 1, not the display device. Alternatively, the display device may include the display module 11 and the power module 54, and the power module 54 may supply power to the elements such as the processor 51 and the memory 52 of the electronic device 1. However, various modifications may be made.

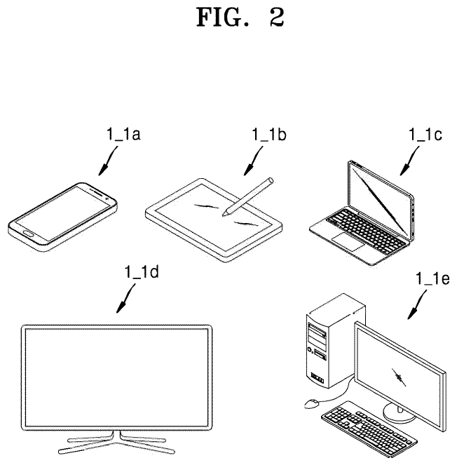

FIG. 2 is a schematic view of the electronic device 1 according to some example embodiments.

FIG. 2 shows, as an example of the electronic device 1, a smartphone 1_1a, a tablet personal computer (PC) 1_1b, a laptop 1_1c, and a TV 1_1d, and a desk monitor 1_1e.

The smartphone 1_1a may include not only the processor 51, the memory 52, the power module 54, and the display module 11, but also the input module 55 such as a touch sensor, and the communication module 57. The smartphone 1_1a may process information received through the communication module 57 or other input modules and display the information through the display module 11.

Similar to the smartphone 1_1a, the tablet personal computer (PC) 1_1b, the laptop 1_1c, the TV 1_1d, and/or the desk monitor 1_1e may include the display module 11 and the input module 55 and may include the communication module 57 depending on a case.

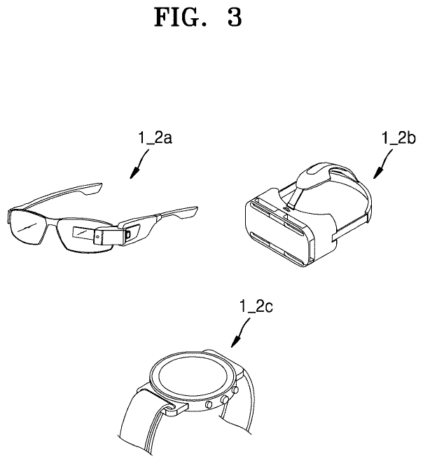

FIG. 3 is a schematic view showing a case where the electronic devices 1 according to some example embodiments are wearable electronic devices.

FIG. 3 shows, as an example of the electronic device 1, smart glasses 1_2a, a head mount display 1_2b, and a smartwatch 1_2c.

The smart glasses 1_2a and the head mount display 1_2b may include the display module 11 displaying images and a reflector reflecting a display surface displaying the images and providing the images to a user's eyes. A user may experience virtual reality or augmented reality using the electronic device 1.

The smartwatch 1_2c may include a biometric sensor as the input module 55 and provide, through the display module 11, a user with bio information recognized through the biometric sensor.

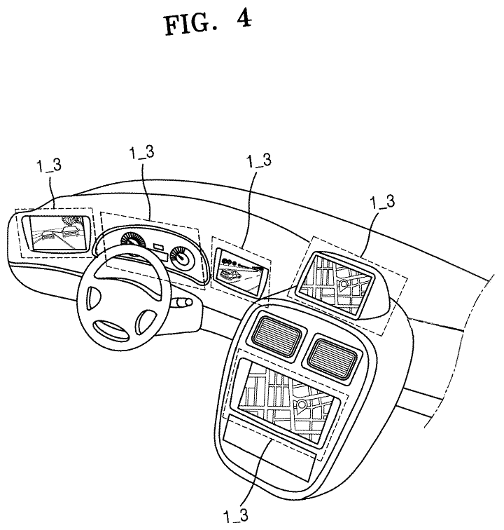

FIG. 4 is a schematic view showing a case where the electronic device 1 according to some example embodiments is a vehicle electronic device 1_3.

As shown in FIG. 4, the vehicle electronic device 1_3 may be included in an instrument board, a center facia or the like of an automobile, or may be a center information display (CID) disposed on a dashboard of an automobile or a room mirror display replacing a side mirror.

However, the electronic device 1 according to the disclosed example embodiments are not limited thereto. As an example, the electronic device 1 according to some example embodiments may include not only devices centered on displays such as billboards, electronic boards, and/or game consoles, but also various home appliances that display information through the display module 11, such as a refrigerator, a washing machine, a dryer, an air conditioner, and/or a robot vacuum cleaner. In some example embodiments, the display module 11 has a function of transmitting light, the electronic device 1 may be a smart window or a transparent display device displaying a background and display images together. However, the electronic device 1 according to the disclosed example embodiments are not limited thereto. As long as the electronic device 1 includes the display panel 10 described below, any electronic device may fall within the scope of the disclosure.

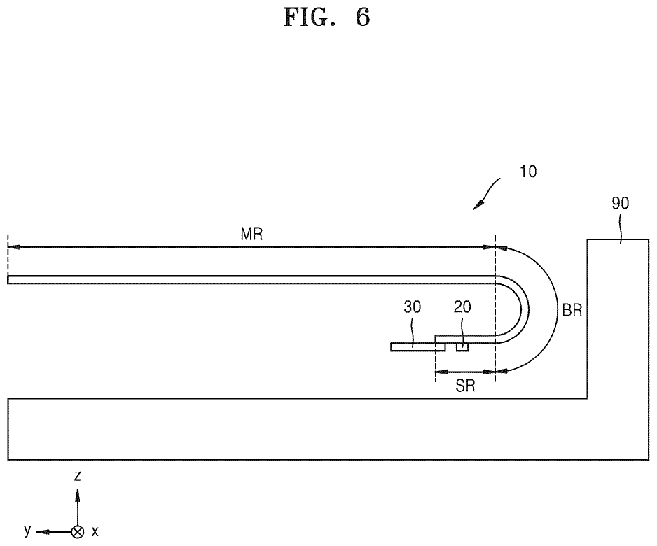

FIG. 5 is a schematic plan view of the display module 11 including the display panel 10 according to some example embodiments, and FIG. 6 is a schematic side view of the display module 11 of FIG. 5. The electronic device 1 may include the display module 11 shown in FIGS. 5 and 6.

The display panel 10 may include a display area DA and a peripheral area PA outside the display area DA. The display area DA is a region in which images are displayed and a plurality of pixels may be disposed in the display area DA. The display area DA may have various shapes, for example, circular shapes, elliptical shapes, polygonal shapes, or shapes of specific figures. It is shown in FIG. 5 that the display area DA has a roughly rectangular shape having round corners.

The peripheral area PA may be located outside the display area DA. The peripheral area PA may include a first peripheral area PA1 and a second peripheral area PA2, wherein the first peripheral area PA1 is disposed to surround at least a portion of the display area DA, and the second peripheral area PA2 is located at the lower end of the display area DA. Hereinafter, assuming the first direction is a y axis direction and the second direction is an x axis direction in the present specification, the second peripheral area PA2 may extend in the second direction (the x axis direction). The width of the second peripheral area PA2 in the second direction (the x axis direction) may be less than the width of the display area DA. At least a portion of the second peripheral area PA2 may be easily bent through this structure.

A planar shape of the display panel 10 shown in FIG. 5 may be substantially equal to the shape of a substrate 100 included in the display panel 10. When the display panel 10 includes the display area DA and the peripheral area PA outside the display area DA, it may represent the substrate 100 includes the display area DA and the peripheral area PA outside the display area DA. Hereinafter, for convenience, description is made on the assumption that the substrate 100 includes the display area DA and the peripheral area PA.

The display panel 10 may include a main region MR, a bent region BR outside the main region MR, and a sub-region SR apart from the main region MR with the bent region BR therebetween. The main region MR may be disposed on one side of the bent region BR, and the sub-region SR may be disposed on another side of the bent region BR. As shown in FIG. 6, the display panel 10 may be bent in the bent region BR, and when viewed from a third direction (e.g., a z axis direction), at least portion of the sub-region SR may overlap the main region MR.

Although it is shown in FIG. 6 that the display panel 10 is bent, example embodiments are not limited thereto. As an example, the display panel 10 may be a foldable display panel, and in this case, the display panel 10 may be bent inside the display area DA around a bending axis crossing the display area DA. In some example embodiments, the display panel 10 may not be bent. The sub-region SR may be a non-display area.

The data driver 20 may be disposed in the sub-region SR of the display panel 10 included in the display module 11. The data driver 20 may be disposed on the display panel 10 in the form of an integrated circuit (IC). As an example, the data driver 20 may be a data driving integrated circuit generating data signals.

A display circuit board 30 may be attached to the end of the sub-region SR of the display panel 10. That is, in some example embodiments, the display module 11 may include the display circuit board 30. The display circuit board 30 may be electrically connected to the data driver 20 or the like through a pad of the sub-region SR of the display panel 10.

As shown in FIG. 6, a lower cover 90 may form the exterior of the electronic device 1, and may have an opening exposing a portion of the display panel 10. The lower cover 90 may be fastened to the display panel 10 such that a surface thereof corresponding to the display panel 10 is exposed. The lower cover 90 may be located on the opposite side of a cover window (not shown) with the display panel 10 therebetween. The lower cover 90 may form the lower exterior of the electronic device 1. The lower cover 90 may include plastic, metal, or both plastic and metal.

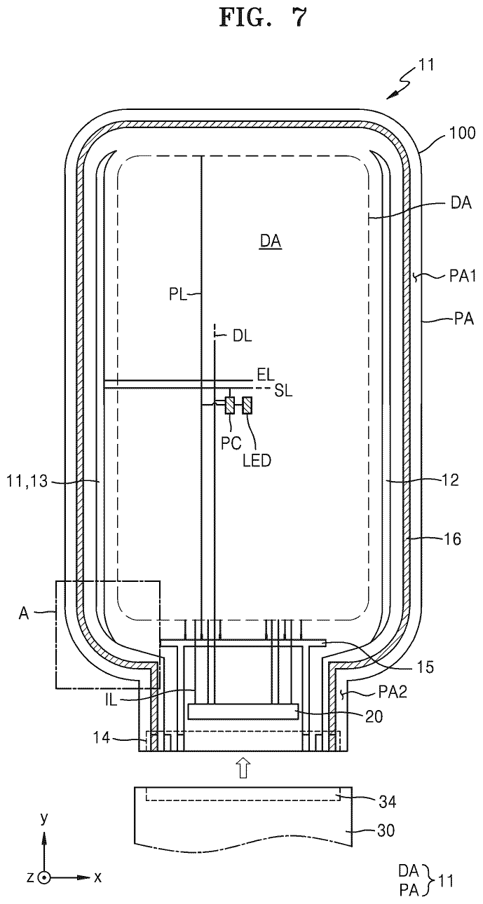

FIG. 7 is a schematic plan view of the display module 11 of FIG. 5.

As shown in FIG. 7, the display panel 10 included in the display module 11 may include the substrate 100. Various elements forming the display panel 10 may be disposed on the substrate 100.

The substrate 100 may include glass, ceramic, metal, or polymer resin. The substrate 100 may include polymer resin such as polyethersulphone, polyacrylate, polyetherimide, polyethylene naphthalate, polyethylene terephthalate, polyphenylene sulfide, polyarylate, polyimide, polycarbonate, or cellulose acetate propionate. The substrate 100 may have a multi-layered structure including two layers including the above-described polymer resin, and an inorganic material layer disposed therebetween. Alternatively, the substrate 100 may have a structure in which a layer including the polymer resin and an inorganic material layer are alternately stacked. The inorganic material layer may include, for example, silicon oxide, silicon nitride, or silicon oxynitride. However, example embodiments are not limited thereto.

The pixels may be disposed in the display area DA, and the display area DA may display images using light emitted from the pixels. Each pixel may include a light-emitting diode LED, and the light-emitting diode LED may be electrically connected to a pixel circuit PC. The pixel circuit PC and the light-emitting diode LED may be disposed in the display area DA. For convenience, although it is shown in FIG. 7 that the pixel circuit PC and the light-emitting diode LED are located side-by-side, the pixel circuit PC may actually at least partially overlap the light-emitting diode LED. As an example, the light-emitting diode LED may be disposed on the pixel circuit PC.

A gate driving circuit, a pad 14, a first power supply line 15, and a second power supply line 16 may be disposed in the peripheral area PA. The gate driving circuit may include, for example, a first scan driving circuit 11, a second scan driving circuit 12, and/or an emission control driving circuit 13.

The first scan driving circuit 11 may be configured to provide scan signals to the pixel circuit PC through a gate line SL. The second scan driving circuit 12 may be disposed opposite the first scan driving circuit 11 with the display area DA therebetween. Some of the pixel circuits PC disposed in the display area DA may be electrically connected to the first scan driving circuit 11, and the others may be connected to the second scan driving circuit 12. Depending on a case, the second scan driving circuit 12 may be omitted.

Like the first scan driving circuit 11, the emission control driving circuit 13 may be disposed on one side of the display area DA. The emission control driving circuit 13 may provide emission control signals to a pixel P through an emission control line EL. Although it is shown in FIG. 7 that the emission control driving circuit 13 is disposed on only one side of the display area DA, example embodiments are not limited thereto. For example, the display panel 10 may include the emission control driving circuits 13 disposed on one side and another side of the display area DA. Alternatively, the display panel 10 may include the first scan driving circuit 11 disposed on one side of the display area DA, and the emission control driving circuit 13 disposed on the other side of the display area DA.

The pad 14 may be disposed in the second peripheral area PA2 of the substrate 100. The pad 14 may be exposed by not being covered by an insulating layer, and may be electrically connected to the display circuit board 30. A pad 34 of the display circuit board 30 may be electrically connected to the pad 14 of the display panel 10.

The display circuit board 30 is configured to transfer signals or power of a controller to the display panel 10. Control signals generated by the controller may be transferred to the gate driving circuit through the display circuit board 30. In addition, the controller may provide a first power voltage ELVDD and a second power voltage ELVSS to the first power supply line 15 and the second power supply line 16. The first power voltage ELVDD (referred to as a driving voltage, hereinafter) may be provided to each pixel circuit PC through a driving voltage line PL connected to the first power supply line 15, and the second power voltage ELVSS (referred to as a common voltage, hereinafter) may be provided to a common electrode of the light-emitting diode LED connected to the second power supply line 16. The first power supply line 15 may extend in the second direction (the x axis direction). The second power supply line 16 may have a loop shape having one open side and partially surround the display area DA.

Data signals of the data driver 20 may be transferred to the pixel circuit PC through a data line DL electrically connected to an input line IL through the input line IL.

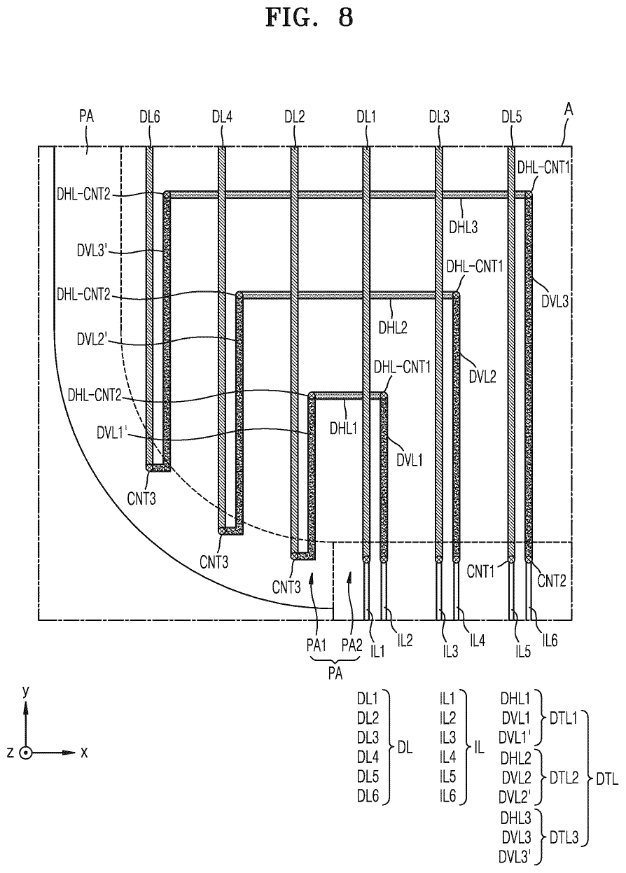

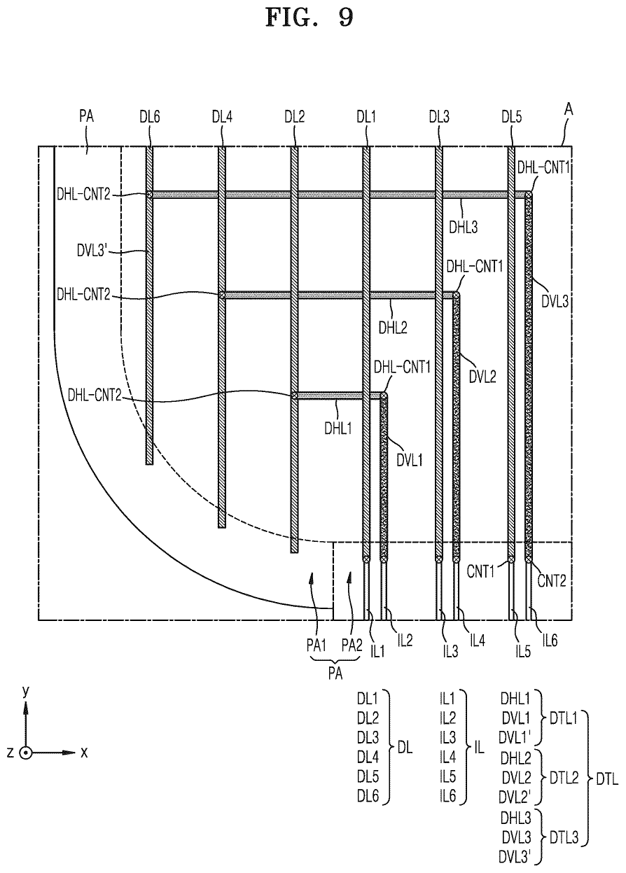

FIG. 8 is a schematic enlarged conceptual view of a region A of the display module 11 of FIG. 7, and FIG. 9 is a view of a modification of FIG. 8.

As shown in FIG. 8, the data line DL extending in the first direction (the y axis direction) is disposed in the display area DA, and the input line IL is disposed in the peripheral area PA. The input line IL may transfer data signals of the data driver 20 to the data line DL. For convenience of illustration, although FIG. 8 shows that the data line DL includes a first data line DL1, a second data line DL2, a third data line DL3, a fourth data line DL4, a fifth data line DL5, and a sixth data line DL6, and the input line IL includes a first input line IL1, a second input line IL2, a third input line IL3, a fourth input line IL4, a fifth input line IL5, and a sixth input line IL6, the number of the data lines DL and the number of the input lines IL may be variously changed.

Some of the data lines DL may be directly connected to a corresponding input line IL, but other some of the data lines DL may be electrically connected to a corresponding input line IL through a data transfer line DTL.

The first data line DL1, the third data line DL3, and the fifth data line DL5 may receive data signals from the first input line IL1, the third input line IL3, and the fifth input line IL5. The first data line DL1, the third data line DL3, and the fifth data line DL5 may be electrically connected to the first input line IL1, the third input line IL3, and the fifth input line IL5. Each of the first data line DL1, the third data line DL3, and the fifth data line DL5 may be integrally formed with a corresponding one of the first input line IL1, the third input line IL3, and the fifth input line IL5. Alternatively, each of the first data line DL1, the third data line DL3, and the fifth data line DL5 may be electrically connected to a corresponding one of the first input line IL1, the third input line IL3, and the fifth input line IL5 through a first contact hole CNT1, as shown in FIG. 8.

The second data line DL2, the fourth data line DL4, and the sixth data line DL6 may be electrically connected to the second input line IL2, the fourth input line IL4, and the sixth input line IL6 through a first data transfer line DTL1, a second data transfer line DTL2, and a third data transfer line DTL3. That is, the second input line IL2 may be electrically connected to the second data line DL2 through the first data transfer line DTL1, the fourth input line IL4 may be electrically connected to the fourth data line DL4 through the second data transfer line DTL2, and the sixth input line IL6 may be electrically connected to the sixth data line DL6 through the third data transfer line DTL3.

Most of each of the first data transfer line DTL1, the second data transfer line DTL2, and the third data transfer line DTL3 may be located within the display area DA. One end of each of the first data transfer line DTL1, the second data transfer line DTL2, and the third data transfer line DTL3 may be electrically connected to a corresponding one of the second input line IL2, the fourth input line IL4, and the sixth input line IL6 through a second contact hole CNT2. Another end of each of the first data transfer line DTL1, the second data transfer line DTL2, and the third data transfer line DTL3 may be electrically connected to a corresponding one of the second data line DL2, the fourth data line DL4, and the sixth data line DL6 through a third contact hole CNT3. For reference, although it is shown in FIG. 8 that the second contact hole CNT2 and the third contact hole CNT3 are located in the peripheral area PA, example embodiments are not limited thereto. As an example, the second contact hole CNT2 and/or the third contact hole CNT3 may be located in the display area DA.

The first data transfer line DTL1 may include a first horizontal connection line DHL1, a first vertical connection line DVL1, and a first additional vertical connection line DVL1′, the second data transfer line DTL2 may include a second horizontal connection line DHL2, a second vertical connection line DVL2, and a second additional vertical connection line DVL2′, and the third data transfer line DTL3 may include a third horizontal connection line DHL3, a third vertical connection line DVL3, and a third additional vertical connection line DVL3′. The first horizontal connecting line DHL1, the second horizontal connecting line DHL2, and the third horizontal connecting line DHL3 may extend approximately in the second direction (the x axis direction). The first vertical connection line DVL1, the second vertical connection line DVL2, the third vertical connection line DVL3, the first additional vertical connection line DVL1′, the second additional vertical connection line DVL2′, and the third additional vertical connection line DVL3′ may extend approximately in the first direction (the y axis direction) and may be substantially parallel to the data line DL.

Each of the second input line IL2, the fourth input line IL4, and the sixth input line IL6 may be electrically connected to a corresponding one of the first vertical connection line DVL1, the second vertical connection line DVL2, and the third vertical connection line DVL3 through the second contact hole CNT2, and each of the second data line DL2, the fourth data line DL4, and the sixth data line DL6 may be electrically connected to a corresponding one of the first additional vertical connection line DVL1′, the second additional vertical connection line DVL2′, and the third additional vertical connection line DVL3′ through the third contact hole CNT3. Each of the first horizontal connecting line DHL1, the second horizontal connecting line DHL2, and the third horizontal connecting line DHL3 may be electrically connected to a corresponding one of the first vertical connecting line DVL1, the second vertical connecting line DVL2, and the third vertical connecting line DVL3 through a first connecting contact hole DHL-CNT1, and may be electrically connected to a corresponding one of the first additional vertical connecting line DVL1′, the second additional vertical connecting line DVL2′, and the third additional vertical connecting line DVL3′ through a second connecting contact hole DHL-CNT2.

The first vertical connecting line DVL1, the second vertical connecting line DVL2, the third vertical connecting line DVL3, the first additional vertical connecting line DVL1′, the second additional vertical connecting line DVL2′, and the third additional vertical connecting line DVL3′ may be disposed on the same first layer, and the first horizontal connecting line DHL1, the second horizontal connecting line DHL2, and the third horizontal connecting line DHL3 may be disposed on a second layer which is different from the first layer. For reference, when certain elements are disposed on the same layer, those elements may be formed simultaneously using the same material through the same mask process.

As described above, FIG. 8 shows that the first data transfer line DTL1 includes a first horizontal connection line DHL1, a first vertical connection line DVL1, and a first additional vertical connection line DVL1′, the second data transfer line DTL2 includes a second horizontal connection line DHL2, a second vertical connection line DVL2, and a second additional vertical connection line DVL2′, and the third data transfer line DTL3 includes a third horizontal connection line DHL3, a third vertical connection line DVL3, and a third additional vertical connection line DVL3′. However, example embodiments are not limited thereto.

As an example, as shown in FIG. 9, which is a schematic enlarged conceptual diagram of a portion of the display panel 10 according to some example embodiments, a first data transfer line DTL1 may include a first horizontal connection line DHL1 and a first vertical connection line DVL1, a second data transfer line DTL2 may include a second horizontal connection line DHL2 and a second vertical connection line DVL2, and a third data transfer line DTL3 may include a third horizontal connection line DHL3 and a third vertical connection line DVL3. In this case, each of the first horizontal connection line DHL1, the second horizontal connection line DHL2, and the third horizontal connection line DHL3 may be electrically connected to a corresponding one of the first vertical connection line DVL1, the second vertical connection line DVL2, and the third vertical connection line DVL3 through the first connection contact hole DHL-CNT1, and may be electrically connected to a corresponding one of the second data line DL2, the fourth data line DL4, and the sixth data line DL6 through the second connection contact hole DHL-CNT2.

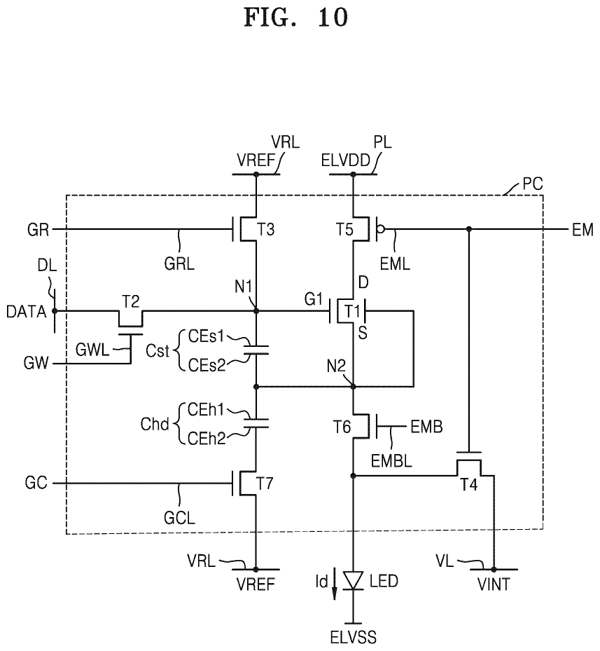

FIG. 10 is an equivalent circuit diagram of a pixel disposed in a display area DA of the display panel 10 included in the display module 11 of FIG. 7.

As shown in FIG. 10, the pixel circuit PC connected to the light-emitting diode LED may include a plurality of transistors and a plurality of capacitors. As an example, the pixel circuit PC may include a first transistor T1, a second transistor T2, a third transistor T3, a fourth transistor T4, a fifth transistor T5, a sixth transistor T6, a seventh transistor T7, a storage capacitor Cst, and a hold capacitor Chd.

The first transistor T1 may be a driving transistor outputting a driving current corresponding to a data signal, and the second transistor T2, the third transistor T3, the fourth transistor T4, the fifth transistor T5, the sixth transistor T6, and the seventh transistor T7 may be switching transistors transferring signals through on/off operations. A first terminal (a first electrode) of each of the first transistor T1, the second transistor T2, the third transistor T3, the fourth transistor T4, the fifth transistor T5, the sixth transistor T6, and the seventh transistor T7 may be one of a source region and a drain region, and a second terminal (a second electrode) may be the other.

At least one of the first transistor T1, the second transistor T2, the third transistor T3, the fourth transistor T4, the fifth transistor T5, the sixth transistor T6, and the seventh transistor T7 may be a p-channel metal oxide semiconductor field effect transistor (PMOS), and the rest of the transistors may be n-channel metal oxide semiconductor field effect transistors (NMOSs). As an example, the fifth transistor T5 may be a PMOS, and the second transistor T2, the third transistor T3, the fourth transistor T4, the sixth transistor T6, and the seventh transistor T7 may be NMOSs. Alternatively, the fifth transistor T5 and the sixth transistor T6 may be PMOSs, and the first transistor T1, the second transistor T2, the third transistor T3, the fourth transistor T4, and the seventh transistor T7 may be NMOSs. Alternatively, all the transistors may be NMOSs or all the transistors may be PMOSs.

At least one of the transistors may be a transistor having a low-temperature polycrystalline silicon (LTPS) semiconductor layer, and the remaining transistors may be transistors having an oxide semiconductor layer. As an example, the fifth transistor T5 may include a semiconductor layer including polycrystalline silicon having high reliability, and each of the remaining transistors may include an oxide semiconductor layer having characteristics of a high carrier mobility and a low leakage current. Hereinafter, a case where the fifth transistor T5 is a PMOS including a silicon semiconductor layer, and the remaining transistors are NMOSs including an oxide semiconductor layer is described.

The pixel circuit PC may be electrically connected to gate lines transferring signals to a gate electrode of each of the transistors. As an example, the pixel circuit PC may be connected to a scan line GWL transferring a scan signal GW, a first reference gate line GRL transferring a first reference signal GR, a second reference gate line GCL transferring a second reference signal GC, a first emission control line EML transferring a first emission control signal EM, a second emission control line EMBL transferring a second emission control signal EMB, and a data line DL transferring a data signal DATA. In addition, the pixel circuit PC may be connected to a driving voltage line PL transferring a driving voltage ELVDD, a reference voltage line VRL transferring a reference voltage VREF, and an initialization voltage line VL transferring an initialization voltage VINT.

The first transistor T1, which is a driving transistor, may be electrically connected between the driving voltage line PL and a second node N2. The first transistor T1 may include a first gate electrode G1 connected to a first node N1, a first terminal electrically connected to the driving voltage line PL, and a second terminal connected to the second node N2. The first terminal may be a drain region D, and the second terminal may be a source region S. The first terminal of the first transistor T1 may be electrically connected to the driving voltage line PL through the fifth transistor T5, and the second terminal of the first transistor T1 may be electrically connected to a pixel electrode of a light-emitting diode LED through the sixth transistor T6. The first transistor T1 may receive a data signal DATA according to a switching operation of the second transistor T2 and be configured to control the amount of driving current flowing through the light-emitting diode LED.

The second transistor T2, which is a data-write transistor, may be electrically connected between the data line DL and the first node N1. The second transistor T2 may include a gate electrode, a first terminal, and a second terminal, wherein the gate electrode is connected to the scan line GWL, the first terminal is connected to the data line DL, and the second terminal is connected to the first node N1. The second transistor T2 may be turned on according to a scan signal GW transferred to the scan line GWL to electrically connect the data line DL to the first node N1 and transfer a data signal DATA to the first node N1, the data signal DATA being transferred from the data line DL.

The third transistor T3, which is a first initialization transistor, may be electrically connected between the first node N1 and the reference voltage line VRL. The third transistor T3 may include a gate electrode, a first terminal, and a second terminal, wherein the gate electrode is connected to the first reference gate line GRL, the first terminal is connected to the first node N1, and the second terminal is connected to the reference voltage line VRL. The third transistor T3 may be turned on according to a first reference signal GR transferred to the first reference gate line GRL and may transfer the reference voltage VREF to the first node N1, the reference voltage VREF being from the reference voltage line VRL.

The fourth transistor T4, which is a second initialization transistor, may be electrically connected between the first transistor T1 and the initialization voltage line VL. Specifically, the fourth transistor T4 may be electrically connected between the sixth transistor T6 and the initialization voltage line VL. The fourth transistor T4 may include a gate electrode, a first terminal, and a second terminal, wherein the gate electrode is connected to the first emission control line EML, the first terminal is connected to the second terminal of the sixth transistor T6 and the light-emitting diode LED, and the second terminal is connected to the initialization voltage line VL. The fourth transistor T4 may be turned on according to a first emission control signal EM transferred to the first emission control line EML and may transfer the initialization voltage VINT to the pixel electrode of the light-emitting diode LED, the initialization voltage VINT being from the initialization voltage line VL. That is, the fourth transistor T4 may initialize the potential of the pixel electrode of the light-emitting diode Led to the initialization voltage VINT.

The fifth transistor T5, which is an emission control transistor, may be electrically connected between the driving voltage line PL and the first transistor T1. The fifth transistor T5 may include a gate electrode, a first terminal, and a second terminal, wherein the gate electrode is connected to the first emission control line EML, the first terminal is connected to the driving voltage line PL, and the second terminal is connected to the first terminal of the first transistor T1. The fifth transistor T5 may be turned on or turned off according to a first emission control signal EM from the first emission control line EML.

The sixth transistor T6, which is an operation control transistor, may be connected between the first transistor T1 and the light-emitting diode LED. The sixth transistor T6 may include a gate electrode, a first terminal, and a second terminal, wherein the gate electrode is connected to the second emission control line EMBL, the first terminal is connected to the second node N2, and the second terminal is connected to the light-emitting diode LED. The sixth transistor T6 may be turned on according to a second emission control signal EMB from the second emission control line EMBL and may electrically connect the second node N2 to the pixel electrode of the light-emitting diode LED.

For reference, although it is shown in FIG. 10 that the fifth transistor T5 operates in response to a first emission control signal EM, and the sixth transistor T6 operates in response to a second emission control signal EMB, the example embodiments are not limited thereto. As an example, the fifth transistor T5 and the sixth transistor T6 may operate in response to the same emission control signal.

For reference, a first reference signal GR may be substantially synchronized with a scan signal GW of the pixel circuit PC located in a previous row. A second reference signal GC described below may be also substantially synchronized with a scan signal GW of the pixel circuit PC located in the previous row, or be substantially synchronized with a scan signal GW or a first reference signal GR of the pixel circuit PC located in the next row.

The storage capacitor Cst may be electrically connected between the first node N1 and the second node N2. That is, the pixel circuit PC included in the display panel according to some example embodiments may be a source-follower type circuit in which the storage capacitor Cst is connected between the first node N1 and the second node N2. A first storage electrode CEs1 of the storage capacitor Cst may be connected to the first node N1, and a second storage electrode CEs2 may be connected to the second node N2. The storage capacitor Cst may store a threshold voltage of the first transistor T1 and a voltage corresponding to a data signal DATA.

The hold capacitor Chd may be connected between the seventh transistor T7 and the second node N2. A first hold electrode CEh1 of the hold capacitor Chd may be electrically connected to the second node N2, and a second hold electrode CEh2 may be electrically connected to the reference voltage line VRL through the seventh transistor T7. The hold capacitor Chd may ensure that a voltage of the second node N2 of the first transistor T1 does not fluctuate and has a constant voltage when a surrounding signal fluctuates.

The seventh transistor T7, which is a third initialization transistor, may be connected between the second hold electrode CEh2 of the hold capacitor Chd and the reference voltage line VRL. The seventh transistor T7 may include a gate electrode, a first terminal, and a second terminal, wherein the gate electrode is connected to the second reference gate line GCL, the first terminal is connected to the second hold electrode CEh2 of the hold capacitor Chd, and the second terminal is connected to the reference voltage line VRL. The seventh transistor T7 may be turned on according to a second reference signal GC transferred to the second reference gate line GCL and may transfer the reference voltage VREF to the second hold electrode CEh2 of the hold capacitor Chd, the reference voltage VREF being from the reference voltage line VRL.

The light-emitting diode LED may include the pixel electrode and a common electrode over the pixel electrode, wherein the pixel electrode is electrically connected to the second node N2 through the sixth transistor T6, and the common electrode may receive the common voltage ELVSS. The common electrode may be an integral body over a plurality of light-emitting diodes LED.

Although it is shown in FIG. 10 that the pixel circuit PC includes seven transistors and two capacitors, the example embodiments are not limited thereto. As an example, the pixel circuit PC may include five transistors and two capacitors. The pixel circuit PC may include six transistors and one or two capacitors.

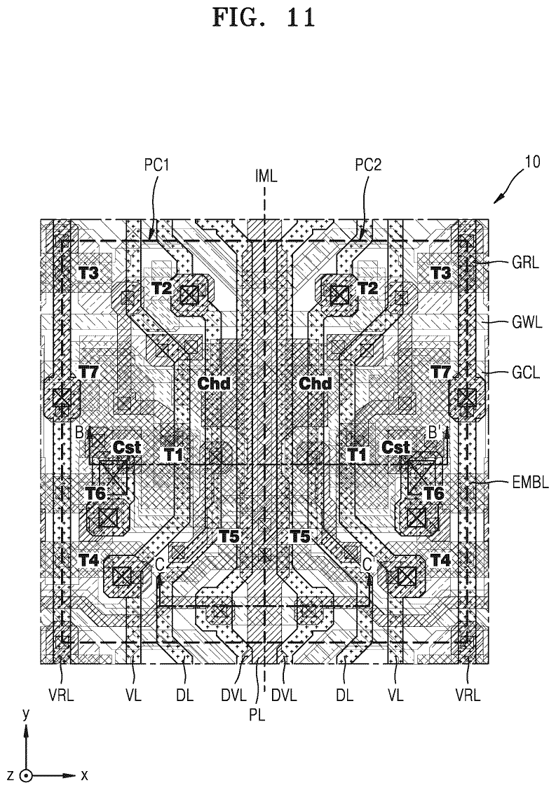

FIG. 11 is a schematic arrangement view showing the positions of transistors and a capacitor and the like in pixels disposed in the display area of the display panel 10 included in the display module 11.

For convenience of description, FIG. 11 shows two pixel circuits, for example, a first pixel circuit PC1 and a second pixel circuit PC2 disposed in the same row in the second direction (the x axis direction). However, example embodiments are not limited thereto. In addition, although it is shown in FIG. 11 that the first pixel circuit PC1 and the second pixel circuit PC2 are approximately mirror-symmetrical to each other with respect to an imaginary line IML extending in the first direction (the y axis direction) therebetween, the example embodiments are not limited thereto. The display panel 10 may include a plurality of pixel circuits disposed to form a row in the second direction (the x axis direction) and a column in the first direction (the y axis direction).

As shown in FIG. 11, each of the first pixel circuit PC1 and the second pixel circuit PC2 may include transistors and capacitors. As an example, each of the first pixel circuit PC1 and the second pixel circuit PC2 may include the first to seventh transistors T1 to T7, the storage capacitor Cst, and the hold capacitor Chd described above with reference to FIG. 10. That is, when taking into account the first pixel circuit PC1 and the second pixel circuit PC2, two first transistors T1 may be disposed adjacent to each other in the second direction (the x axis direction).

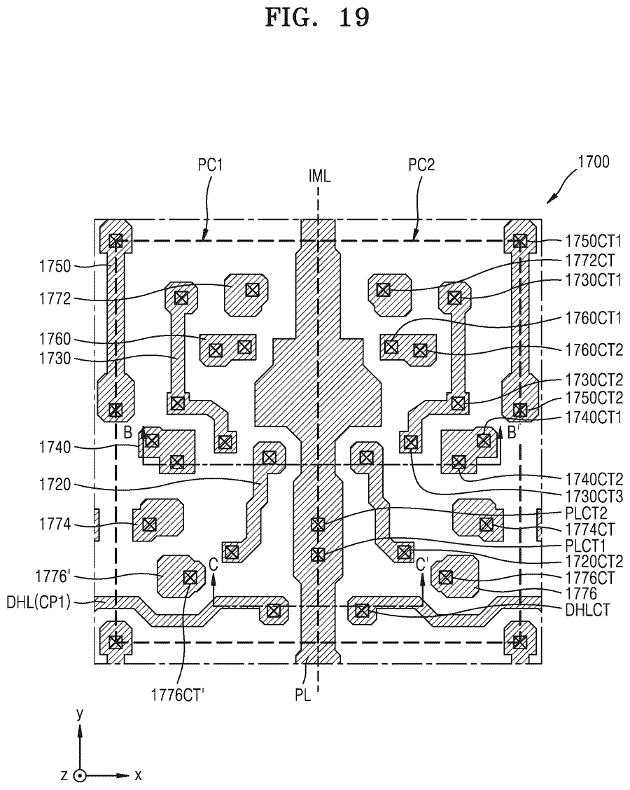

The gate lines electrically connected to the first pixel circuit PC1 and the second pixel circuit PC2, for example, the scan line GWL, the first reference gate line GRL, the second reference gate line GCL, the first emission control line EML, and the second emission control line EMBL may approximately extend in the second direction (the x axis direction). Besides, a horizontal connection line DHL (see FIG. 19) may also approximately extend in the second direction (the x axis direction).

The first pixel circuit PC1 may be electrically connected to the data line DL passing by the first pixel circuit PC1, and the second pixel circuit PC2 may be electrically connected to the data line DL passing by the second pixel circuit PC2. The data line DL may approximately extend in the first direction (e.g., the y direction). The date line DL electrically connected to the first pixel circuit PC1 and the date line DL electrically connected to the second pixel circuit PC2 may be symmetrical to each other with respect to the imaginary line IML described above.

The first pixel circuit PC1 may be electrically connected to a voltage line, for example, the reference voltage line VRL and the initialization voltage line VL passing by the first pixel circuit PC1. The second pixel circuit PC2 may be electrically connected to a voltage line, for example, the reference voltage line VRL and the initialization voltage line VL passing by the second pixel circuit PC2. The reference voltage line VRL and the initialization voltage line VL electrically connected to the first pixel circuit PC1 and the reference voltage line VRL and the initialization voltage line VL electrically connected to the second pixel circuit PC2 may be symmetrical to each other with respect to the imaginary line IML described above. Each of the reference voltage line VRL and the initialization voltage line VL may approximately extend in the first direction (the y axis direction). For convenience, the initialization voltage line VL passing by the first pixel circuit PC1 may be referred to as a first initialization voltage line, and the initialization voltage line VL passing by the second pixel circuit PC2 may be referred to as a second initialization voltage line. That is, first initialization voltage lines and second initialization voltage lines extending in the first direction (the y axis direction) may be alternately disposed in the second direction (the x axis direction).

A vertical connection line DVL may also extend in the first direction (the y axis direction). The vertical connection line DVL may correspond to a portion of the data transfer line DTL described with reference to FIG. 8 or 9, for example, one of the first vertical connection line DVL1, the second vertical connection line DVL2, the third vertical connection line DVL3, the first additional vertical connection line DVL1′, the second additional vertical connection line DVL2′, and the third additional vertical connection line DVL3′. In this case, the vertical connection line DVL may be electrically connected to a data line DL of a pixel circuit disposed in a different column from the first pixel circuit PC1 and the second pixel circuit PC2 shown in FIG. 11 to transfer data signals to pixel circuits in the different column. Alternatively, in some example embodiments, the first pixel circuit PC1 or the second pixel circuit PC2 is not located near the corner of the display area DA as shown in FIG. 8 or 9 but is located in the center of the display area DA, the vertical connection line DVL may be a dummy line to which an electrical signal is not applied, or a dummy line to which a preset electrical signal is applied when needed.

For reference, a horizontal connection line DHL described below may correspond to a portion of the data transfer line DTL described with reference to FIG. 8 or 9, for example, one of the first horizontal connection line DHL1, the second horizontal connection line DHL2, and the third horizontal connection line DHL3. In this case, the horizontal connection line DHL, together with the vertical connection line DVL, may be electrically connected to a data line DL of a pixel circuit disposed in a different column from the first pixel circuit PC1 and the second pixel circuit PC2 shown in FIG. 11 to transfer data signals to pixel circuits in the different column. Alternatively, in some example embodiments the first pixel circuit PC1 or the second pixel circuit PC2 is not located near the corner of the display area DA as shown in FIG. 8 or 9 but is located in the center of the display area DA, the horizontal connection line DHL may be a dummy line to which an electrical signal is not applied, or a dummy line to which a preset electrical signal is applied when needed.

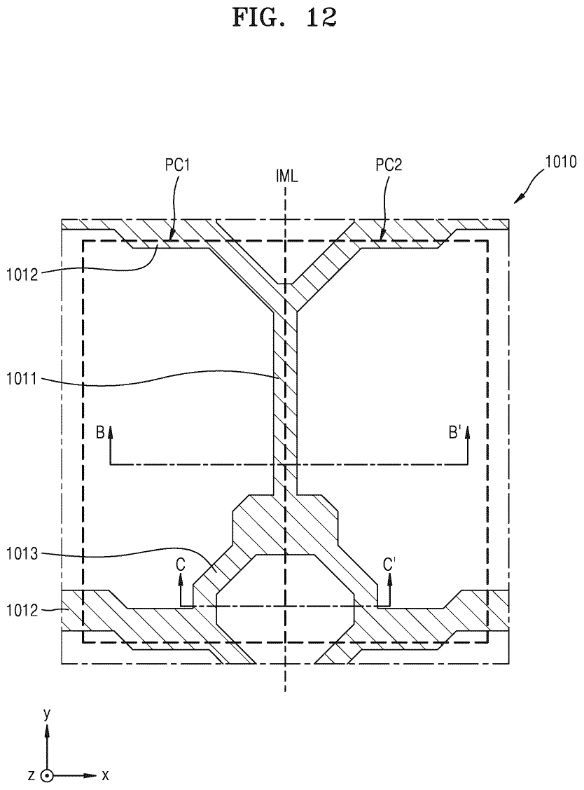

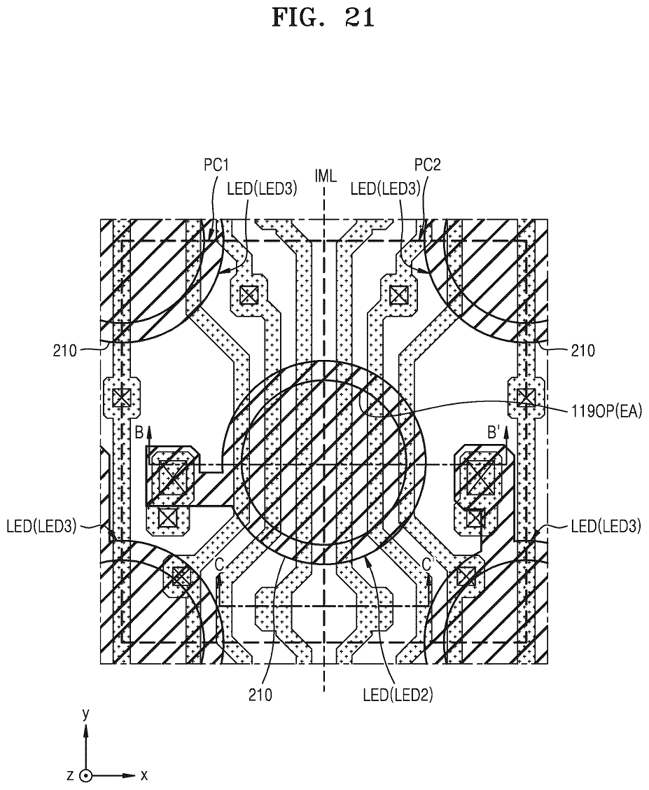

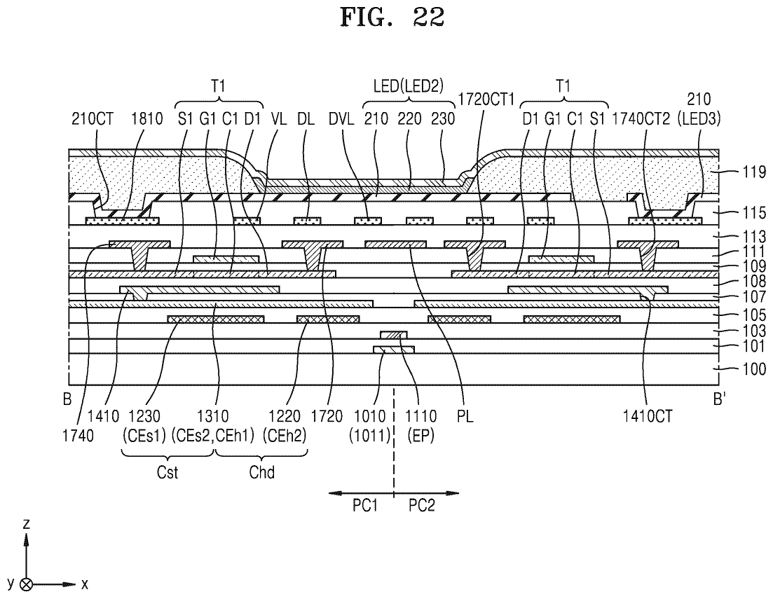

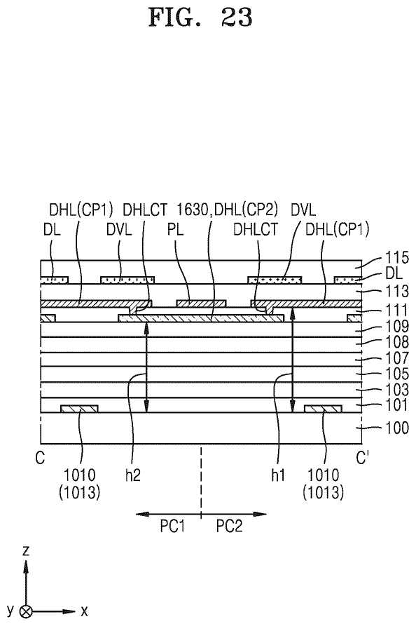

FIGS. 12 to 20 are schematic arrangement views of elements such as transistors and capacitors, for each layer, of the display panel 10 shown in FIG. 11. In addition, FIG. 21 is a schematic arrangement view of pixel electrodes of the display panel 10 of FIG. 11. In addition, FIG. 22 is a schematic cross-sectional view of the display panel 10 taken along line B-B′ of FIGS. 11 to 21. In addition, FIG. 23 is a schematic cross-sectional view of the display panel 10 taken along line C-C′ of FIGS. 11 to 21.

For convenience of description, description is made on a case where the first pixel circuit PC1 is located in an i-th row and a j-th column, and the second pixel circuit PC2 is located in an i-th row and a (j+1)-th column.

The display panel 10 may include a circuit layer including transistors and capacitors disposed on the substrate 100, and a display element layer disposed on the circuit layer and including the light-emitting diode LED. The circuit layer may include the transistors and the capacitors described with reference to FIGS. 10 and 11.

As shown in FIG. 12, a bottom metal layer 1010 may be disposed on the substrate 100. The bottom metal layer 1010 may include a first portion 1011, a second portion 1012, and a third portion 1013, wherein the first portion 1011 extends in the first direction (the y axis direction), and the second portion 1012 and the third portion 1013 extend in the second direction (the x axis direction).

The first portion 1011 of the bottom metal layer 1010 may be located on the imaginary line IML between the first pixel circuit PC1 and the second pixel circuit PC2. The second portion 1012 and the third portion 1013 of the bottom metal layer 1010 may be located on opposite sides with the first portion 1011 therebetween. The second portion 1012 and the third portion 1013 may entirely extend in the first direction (e.g., the x direction) and be locally bent. The bottom metal layer 1010 may include a metal material. Specifically, the bottom metal layer 1010 may include at least one material among aluminum (Al), platinum (Pt), palladium (Pd), silver (Ag), magnesium (Mg), gold (Au), nickel (Ni), neodymium (Nd), iridium (Ir), chrome (Cr), lithium(Li), calcium (Ca), molybdenum (Mo), titanium (Ti), tungsten (W), and copper (Cu). However, example embodiments are not limited thereto. As an example, the bottom metal layer 1010 may have a single-layered structure including molybdenum, a double-layered structure in which a molybdenum layer and a titanium layer are stacked, or a triple-layered structure in which a titanium layer, an aluminum layer, and a titanium layer are stacked.

The bottom metal layer 1010 may have a voltage level of a constant voltage. As an example, the bottom metal layer 1010 may have the same voltage as the driving voltage line PL described above with reference to FIG. 10. That is, the driving voltage ELVDD may be applied to the bottom metal layer 1010. For this purpose, the bottom metal layer 1010 may be electrically connected to a portion of the driving voltage line PL or the first power supply line 15, for example, in the peripheral area PA. The bottom metal layer 1010 may shield at least a portion of light progressing to a fifth semiconductor layer A5 of the fifth transistor T5 and protect the fifth transistor T5 from electrostatic discharge ESD.

A buffer layer 101 may be disposed on the bottom metal layer 1010 to cover the bottom metal layer 1010. The buffer layer 101 may be an inorganic insulating layer including an inorganic insulating material such as silicon oxide, silicon nitride, and/or silicon oxynitride. However, example embodiments are not limited thereto. The buffer layer 101 may have a single-layered structure or a multi-layered structure.

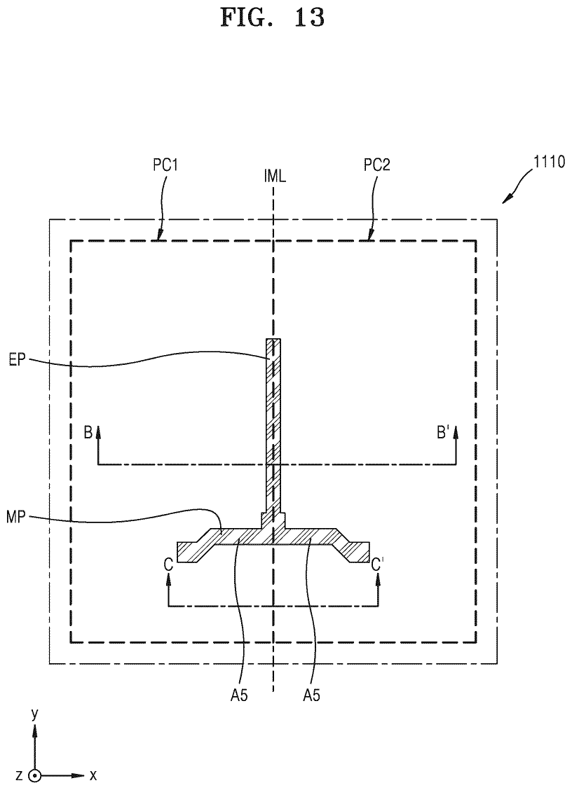

A silicon semiconductor layer 1110 shown in FIG. 13 may be disposed on the buffer layer 101. The silicon semiconductor layer 1110 may include silicon, for example, polycrystalline silicon. However, example embodiments are not limited thereto.

As shown in FIG. 13, the silicon semiconductor layer 1110 may have an isolated shape. In addition, the silicon semiconductor layer 1110 may include a main portion MP having a shape approximately extending in the second direction (the x axis direction) and an extension portion EP having the first direction (the y axis direction) crossing the first direction. The main portion MP and the extension portion EP may be an integral body. The main portion MP of the silicon semiconductor layer 1110 may cross the imaginary line IML between the first pixel circuit PC1 and the second pixel circuit PC2. In addition, the extension portion EP of the silicon semiconductor layer 1110 may overlap the imaginary line IML between the first pixel circuit PC1 and the second pixel circuit PC2 in a plan view. In a plan view, the extension portion EP may be located between the first transistor T1 of the first pixel circuit PC1 and the second transistor T2 of the second pixel circuit PC2. The silicon semiconductor layer 1110 may include the fifth semiconductor layer A5 of each of the first pixel circuit PC1 and the second pixel circuit PC2. In other words, the fifth semiconductor layer A5 of the first pixel circuit PC1 and the fifth semiconductor layer A5 of the second pixel circuit PC2 may be an integral body.

The silicon semiconductor layer 1110 may overlap the bottom metal layer 1010. As an example, the main portion MP of the silicon semiconductor layer 1110 may approximately overlap the third portion 1013 of the bottom metal layer 1010, and the extension portion EP of the silicon semiconductor layer 1110 may overlap the first portion 1011 of the bottom metal layer 1010. Accordingly, the fifth semiconductor layer A5 of each of the first pixel circuit PC1 and the second pixel circuit PC2 may overlap the third portion 1013 of the bottom metal layer 1010.

A first gate insulating layer 103 may be disposed on the silicon semiconductor layer 1110 to cover the silicon semiconductor layer 1110. The first gate insulating layer 103 may be an inorganic insulating layer including an inorganic insulating material such as silicon oxide, silicon nitride, and/or silicon oxynitride. However, example embodiments are not limited thereto. The first gate insulating layer 103 may have a single-layered structure or a multi-layered structure.

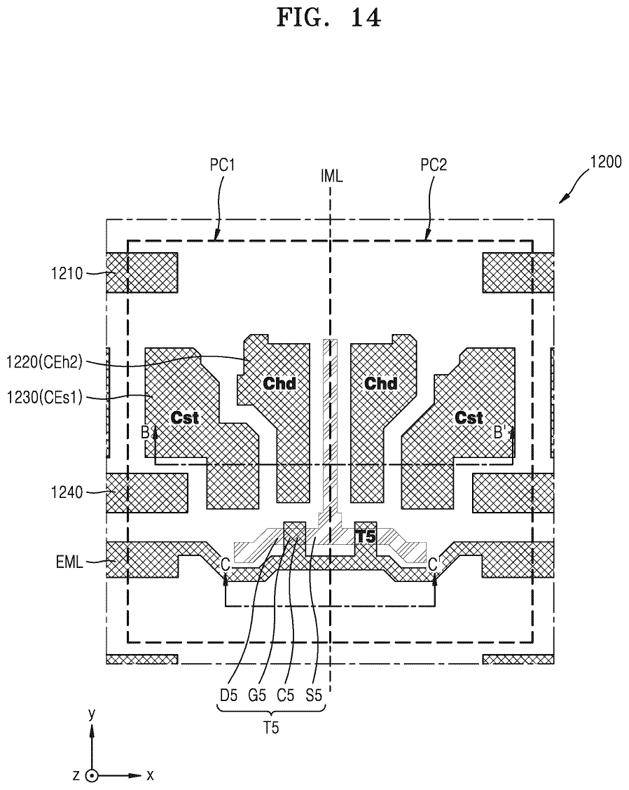

A first gate layer 1200 shown in FIG. 14 may be disposed on the first gate insulating layer 103. For reference, FIG. 14 shows, for convenience, the first gate layer 1200 and the silicon semiconductor layer 1110 thereunder in an overlapping manner. It is shown in FIG. 14 that the first gate layer 1200 includes the first emission control line EML, a first conductive layer 1210, a second conductive layer 1220, a third conductive layer 1230, and a fourth conductive layer 1240. The first emission control line EML, the first conductive layer 1210, the second conductive layer 1220, the third conductive layer 1230, and the fourth conductive layer 1240 of the first pixel circuit PC1, and the first emission control line EML, the first conductive layer 1210, the second conductive layer 1220, the third conductive layer 1230, and the fourth conductive layer 1240 of the second pixel circuit PC2 may be approximately symmetrical to each other with respect to the imaginary line IML between the first pixel circuit PC1 and the second pixel circuit PC2.

As shown in FIG. 14, the first conductive layer 1210, the second conductive layer 1220, the third conductive layer 1230, and the fourth conductive layer 1240 may be apart from each other. The first conductive layer 1210, the second conductive layer 1220, the third conductive layer 1230, and the fourth conductive layer 1240 may include aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu), and may have a single-layered structure or multi-layered structure including these materials. However, example embodiments are not limited thereto. Elements included in the first gate layer 1200 may be simultaneously formed using the same material, and thus, may have the same layer structure.

The first emission control line EML may approximately extend in the second direction (the x axis direction) to pass across the first pixel circuit PC1 and the second pixel circuit PC2. The first emission control line EML may pass across the pixel circuits arranged in the same row as the first pixel circuit PC1 and the second pixel circuit PC2.

The first emission control line EML may include a fifth gate electrode G5 of the fifth transistor T5 of each of the first pixel circuit PC1 and the second pixel circuit PC2. A portion of the first emission control line EML may protrude to overlap the fifth semiconductor layer A5 of the fifth transistor T5, and the protruded portion of the first emission control line EML may correspond to the fifth gate electrode G5 of the fifth transistor T5. The fifth semiconductor layer A5 of the fifth transistor T5 may include a channel region C5 overlapping the fifth gate electrode G5, and conductive regions S5 and D5 respectively disposed on two opposite sides of the channel region C5, wherein the conductive regions S5 and D5 are made conductive by being doped with impurities or plasma-processed. One of the conductive regions S5 and D5 may be a source region and the other may be a drain region. The source region and the drain region may respectively correspond to a source electrode and a drain electrode. The positions of the source region and the drain region may be exchanged depending on the properties of the transistor.

The first conductive layer 1210 may have an isolated shape, and the first conductive layers 1210 may be an integral body in two adjacent pixel circuits. As an example, as shown in FIG. 14, the first conductive layer 1210 belonging to the first pixel circuit PC1 may be an integral body with the first conductive layer 1210 of a pixel circuit located in a −x direction, that is, a pixel circuit located in a (j−1)-th column, and the first conductive layer 1210 belonging to the second pixel circuit PC2 may be an integral body with the first conductive layer 1210 of a pixel circuit located in a +x direction, that is, a pixel circuit located in a (j+2)-th column. Each of the second conductive layer 1220 and the third conductive layer 1230 may have an isolated shape. The fourth conductive layer 1240 may also have an isolated shape and be an integral body in the first pixel circuit PC1 and a pixel circuit in a (j−1)-th column, and in addition, be an integral body in the second pixel circuit PC2 and a pixel circuit in a (j+2)-th column. In the first pixel circuit PC1 and the second pixel circuit PC2, the first conductive layer 1210, the second conductive layer 1220, the third conductive layer 1230, and the fourth conductive layer 1240 may be symmetrical to each other with respect to the imaginary line IML described above.

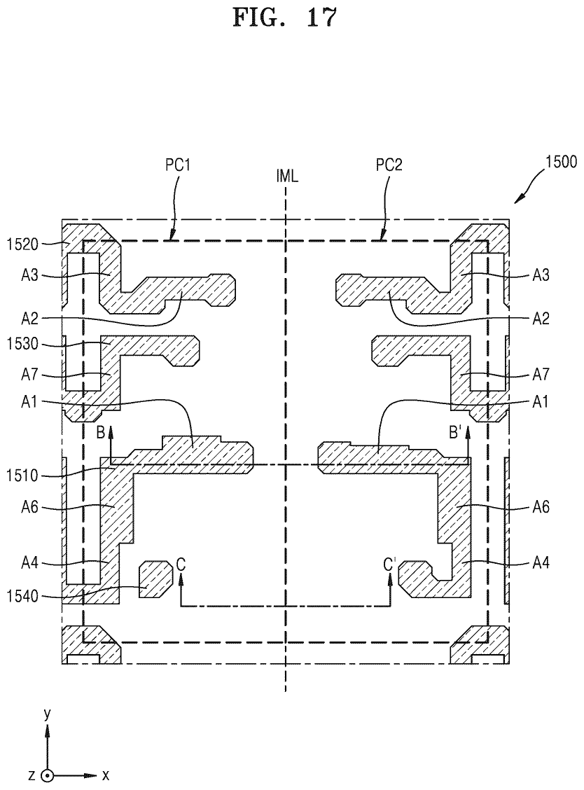

The first conductive layer 1210 may overlap a third semiconductor layer A3 (see FIG. 17) described below. The first conductive layer 1210 may shield at least a portion of light progressing to the third semiconductor layer A3 of the third transistor T3 and protect the third transistor T3 from electrostatic discharge ESD.

The second conductive layer 1220 located in each of the first pixel circuit PC1 and the second pixel circuit PC2 may have an isolated shape, and be located adjacent to the imaginary line IML between the first pixel circuit PC1 and the second pixel circuit PC2. The second conductive layer 1220 may be the second hold electrode CEh2 of the hold capacitor Chd.

The third conductive layer 1230 located in each of the first pixel circuit PC1 and the second pixel circuit PC2 may be the first storage electrode CEs1 of the storage capacitor Cst.

A second gate insulating layer 105 may be disposed to cover the first gate layer 1200. The second gate insulating layer 105 may be an inorganic insulating layer including an inorganic insulating material such as silicon oxide, silicon nitride, and/or silicon oxynitride. The second gate insulating layer 105 may have a single-layered structure or a multi-layered structure. In some example embodiments, the second gate insulating layer 105 may include a material different from a material of the first gate insulating layer 103. As an example, the first gate insulating layer 103 may include silicon oxide, and the second gate insulating layer 105 may include silicon nitride.

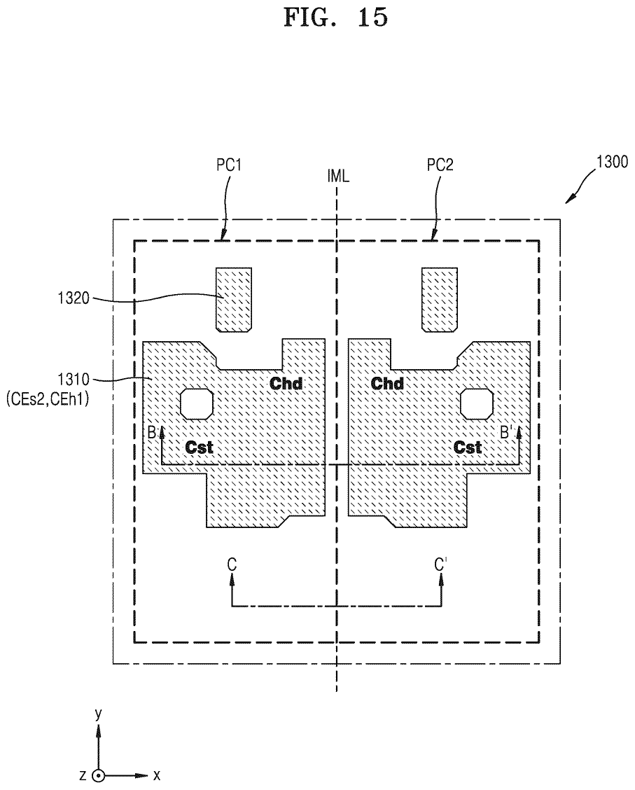

A second gate layer 1300 shown in FIG. 15 may be disposed on the second gate insulating layer 105. It is shown in FIG. 15 that the second gate layer 1300 includes a fifth conductive layer 1310 and a sixth conductive layer 1320. The fifth conductive layer 1310 and the sixth conductive layer 1320 of the first pixel circuit PC1, and the fifth conductive layer 1310 and the sixth conductive layer 1320 of the second pixel circuit PC2 may be approximately symmetrical to each other with respect to the imaginary line IML between the first pixel circuit PC1 and the second pixel circuit PC2.

As shown in FIG. 15, the fifth conductive layer 1310 and the sixth conductive layer 1320 may be disposed apart from each other. The fifth conductive layer 1310 and the sixth conductive layer 1320 may include aluminum (Al), platinum (Pt), palladium (Pd), silver (Ag), magnesium (Mg), gold (Au), Nickel (Ni), neodymium (Nd), iridium (Ir), chrome (Cr), lithium (Li), calcium (Ca), molybdenum (Mo), titanium (Ti), tungsten (W), and/or copper (Cu), and include a single-layered structure or a multi-layered structure including the above materials. However, example embodiments are not limited thereto. Elements included in the second gate layer 1300 may be simultaneously formed using the same material, and thus, may have the same layer structure.

The fifth conductive layer 1310 disposed in each of the first pixel circuit PC1 and the second pixel circuit PC2 may have an isolated shape. The fifth conductive layer 1310 disposed in the first pixel circuit PC1 and the fifth conductive layer 1310 disposed in the second pixel circuit PC2 may be apart from each other and be substantially symmetrical to each other with respect to the imaginary line IML described above. The extension portion EP of the silicon semiconductor layer 1110 may be located between the fifth conductive layer 1310 disposed in the first pixel circuit PC1 and the fifth conductive layer 1310 disposed in the second pixel circuit PC2 in a plan view. The fifth conductive layer 1310 of the first pixel circuit PC1 may overlap the second conductive layer 1220 and the third conductive layer 1230 of the first pixel circuit PC1 located thereunder. The fifth conductive layer 1310 may be the first hold electrode CEh1 of the hold capacitor Chd and the second storage electrode CEs2 of the storage capacitor Cst. That is, the first hold electrode CEh1 of the hold capacitor Chd and the second storage electrode CEs2 of the storage capacitor Cst may be an integral body. Accordingly, the second conductive layer 1220 and the fifth conductive layer 1310 may form the hold capacitor Chd, and the third conductive layer 1230 and the fifth conductive layer 1310 may form the storage capacitor Cst.

The sixth conductive layer 1320 disposed in each of the first pixel circuit PC1 and the second pixel circuit PC2 may also have an isolated shape. The sixth conductive layer 1320 may overlap a second semiconductor layer A2 (see FIG. 17) described below. The sixth conductive layer 1320 may shield at least a portion of light progressing to the second semiconductor layer A2 of the second transistor T2 and protect the second transistor T2 from electrostatic discharge ESD.

A first interlayer insulating layer 107 may be disposed to cover the second gate layer 1300. The first interlayer insulating layer 107 may be an inorganic insulating layer including an inorganic insulating material such as silicon oxide, silicon nitride, and/or silicon oxynitride. However, example embodiments are not limited thereto. The first interlayer insulating layer 107 may have a single-layered structure or a multi-layered structure. As an example, the first interlayer insulating layer 107 may have a stack structure of a layer including silicon oxide and a layer including silicon nitride.

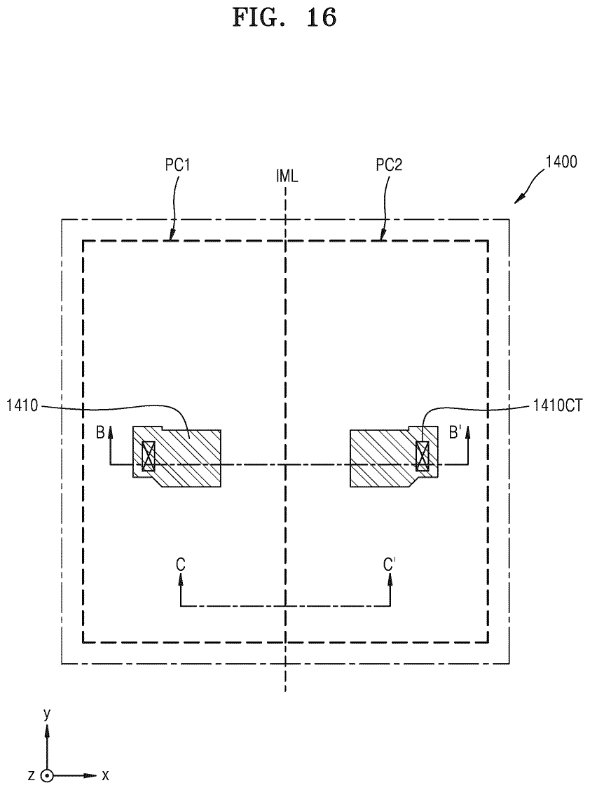

An intermediate conductive layer 1400 shown in FIG. 16 may be disposed on the first interlayer insulating layer 107. It is shown in FIG. 16 that the intermediate conductive layer 1400 includes a shield layer 1410. The shield layer 1410 of the first pixel circuit PC1 and the shield layer 1410 of the second pixel circuit PC2 may be approximately symmetrical to each other with respect to the imaginary line IML between the first pixel circuit PC1 and the second pixel circuit PC2.

The shield layer 1410 may include aluminum (Al), platinum (Pt), palladium (Pd), silver (Ag), magnesium (Mg), gold (Au), Nickel (Ni), neodymium (Nd), iridium (Ir), chrome (Cr), lithium (Li), calcium (Ca), molybdenum (Mo), titanium (Ti), tungsten (W), and/or copper (Cu), and include a single-layered structure or a multi-layered structure including the above materials. However, example embodiments are not limited thereto. As an example, the shield layer 1410 may have a single-layered structure including molybdenum or titanium.

The shield layer 1410 disposed in each of the first pixel circuit PC1 and the second pixel circuit PC2 may have an isolated shape. The shield layer 1410 may overlap a first semiconductor layer A1 (see FIG. 17) described below. The shield layer 1410 may shield at least a portion of light progressing to the first semiconductor layer A1 of the first transistor T1 and protect the first transistor T1 from electrostatic discharge ESD. The shield layer 1410 may be connected to the fifth conductive layer 1310 through a contact hole 1410CT formed in the first interlayer insulating layer 107 thereunder. Accordingly, the shield layer 1410 may have the same electrical potential as the first hold electrode CEh1 of the hold capacitor Chd and the fifth conductive layer 1310, which is the second storage electrode CEs2 of the storage capacitor Cst.

A second interlayer insulating layer 108 may be disposed to cover the intermediate conductive layer 1400. The second interlayer insulating layer 108 may be an inorganic insulating layer including an inorganic insulating material such as silicon oxide, silicon nitride, and/or silicon oxynitride. The second interlayer insulating layer 108 may have a single-layered structure or a multi-layered structure. As an example, the second interlayer insulating layer 108 may have a stack structure of a layer including silicon oxide and a layer including silicon nitride.

A semiconductor layer 1500 shown in FIG. 17 may be disposed on the second interlayer insulating layer 108. The semiconductor layer 1500 may include an oxide semiconductor. The oxide semiconductor may include at least one selected from a group including indium (In), gallium (Ga), stannum (i.e., tin) (Sn), zirconium (Zr), vanadium (V), hafnium (Hf), cadmium (Cd), germanium (Ge), chromium (Cr), titanium (Ti), aluminum (Al), cesium (Cs), cerium (Ce), and zinc (Zn). As an example, the oxide semiconductor may include ITZO(InSnZnO) or IGZO(InGaZnO). However, example embodiments are not limited thereto. It is shown in FIG. 17 that the semiconductor layer 1500 includes a first oxide semiconductor pattern 1510, a second oxide semiconductor pattern 1520, a third oxide semiconductor pattern 1530, and a fourth oxide semiconductor pattern 1540. As shown in FIG. 17, the first oxide semiconductor pattern 1510, the second oxide semiconductor pattern 1520, the third oxide semiconductor pattern 1530, and the fourth oxide semiconductor pattern 1540 may be disposed apart from each other.

The first oxide semiconductor pattern 1510 disposed in each of the first pixel circuit PC1 and the second pixel circuit PC2 may have an isolated shape. The first oxide semiconductor pattern 1510 may include the first semiconductor layer A1, a fourth semiconductor layer A4, and a sixth semiconductor layer A6. That is, the first semiconductor layer A1, the fourth semiconductor layer A4, and the sixth semiconductor layer A6 of the first pixel circuit PC1 may be an integral body, and the first semiconductor layer A1, the fourth semiconductor layer A4, and the sixth semiconductor layer A6 of the second pixel circuit PC2 may be an integral body. The first oxide semiconductor pattern 1510 may have a shape bent by serval times.

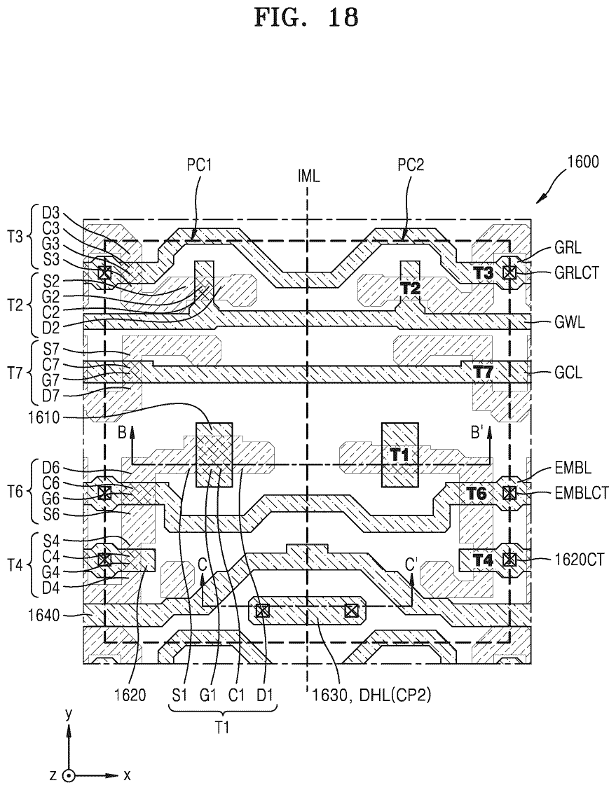

The first semiconductor layer A1, the fourth semiconductor layer A4, and the sixth semiconductor layer A6 included in the first oxide semiconductor pattern 1510 may respectively overlap a first gate electrode 1610, the sixth conductive layer 1620, and the second emission control line EMBL described below with reference to FIG. 18. That is, a portion of the first oxide semiconductor pattern 1510 overlapping the first gate electrode 1610 may be the first semiconductor layer A1, a portion of the first oxide semiconductor pattern 1510 overlapping the sixth conductive layer 1620 may be the fourth semiconductor layer A4, and a portion of the first oxide semiconductor pattern 1510 overlapping the second emission control line EMBL may be the sixth semiconductor layer A6.

For reference, in a plan view, the shape of the first oxide semiconductor pattern 1510 of the first pixel circuit PC1 and the shape of the first oxide semiconductor pattern 1510 of the second pixel circuit PC2 may be different from each other. The first oxide semiconductor pattern 1510 of the first pixel circuit PC1 may be an integral body with a first oxide semiconductor pattern of a pixel circuit disposed in the same row as the first pixel circuit PC and in an adjacent column, for example, a pixel circuit extending in a direction to a pixel circuit disposed in an i-th row and a (j−1)-th column, the pixel circuit being disposed in a (j−1)-th column. Unlike this, the first oxide semiconductor pattern 1510 of the second pixel circuit PC2 may have an isolated shape. In some example embodiments, the first oxide semiconductor pattern 1510 of the first pixel circuit PC1 may also have an isolated shape. In this case, the first oxide semiconductor pattern 1510 of the first pixel circuit PC1 and the first oxide semiconductor pattern 1510 of the second pixel circuit PC2 may be approximately symmetrical to each other with respect to the imaginary line IML between the first pixel circuit PC1 and the second pixel circuit PC2.

The second oxide semiconductor pattern 1520 disposed in each of the first pixel circuit PC1 and the second pixel circuit PC2 may have an isolated shape and be an integral body in two adjacent pixel circuits. As an example, as shown in FIG. 17, the second oxide semiconductor pattern 1520 belonging to the first pixel circuit PC1 may be an integral body with the second oxide semiconductor pattern 1520 of a pixel circuit located in the −x direction, that is, a pixel circuit located in a (j−1)-th column, and the second oxide semiconductor pattern 1520 belonging to the second pixel circuit PC2 may be an integral body with the second oxide semiconductor pattern 1520 of a pixel circuit located in the +x direction, that is, a pixel circuit located in a (j+2)-th column. The second oxide semiconductor pattern 1520 of the first pixel circuit PC1 and the second oxide semiconductor pattern 1520 of the second pixel circuit PC2 may be approximately symmetrical to each other with respect to the imaginary line IML described above.

The second oxide semiconductor pattern 1520 may include the second semiconductor layer A2 of the second transistor T2 and the third semiconductor layer A3 of the third transistor T3. That is, the second semiconductor layer A2 of the second transistor T2 and the third semiconductor layer A3 of the third transistor T3 may be integrally connected to each other. The second semiconductor layer A2 and the third semiconductor layer A3 of the second oxide semiconductor pattern 1520 may overlap the scan line GWL and the first reference gate line GRL described below with reference to FIG. 18. That is, a portion of the second oxide semiconductor pattern 1520 overlapping the scan line GWL may be the second semiconductor layer A2, and a portion of the second oxide semiconductor pattern 1520 overlapping the first reference gate line GRL may be the third semiconductor layer A3.

The third oxide semiconductor pattern 1530 disposed in each of the first pixel circuit PC1 and the second pixel circuit PC2 may have an isolated shape and be an integral body in two adjacent pixel circuits. As an example, as shown in FIG. 17, the third oxide semiconductor pattern 1530 belonging to the first pixel circuit PC1 may be an integral body with the third oxide semiconductor pattern 1530 of a pixel circuit located in the −x direction, that is, a pixel circuit located in a (j−1)-th column, and the third oxide semiconductor pattern 1530 belonging to the second pixel circuit PC2 may be an integral body with the third oxide semiconductor pattern 1530 of a pixel circuit located in the +x direction, that is, a pixel circuit located in a (j+2)-th column. The third oxide semiconductor pattern 1530 of the first pixel circuit PC1 and the third oxide semiconductor pattern 1530 of the second pixel circuit PC2 may be approximately symmetrical to each other with respect to the imaginary line IML described above.

The third oxide semiconductor pattern 1530 may include a seventh semiconductor layer A7 of the seventh transistor T7. The seventh semiconductor layer A7 of the third oxide semiconductor pattern 1530 may overlap the second reference gate line GCL described below with reference to FIG. 1. That is, a portion of the third oxide semiconductor pattern 1530 overlapping the second reference gate line GCL may be the seventh semiconductor layer A7.

The fourth oxide semiconductor pattern 1540 may be disposed in the first pixel circuit PC1. The fourth oxide semiconductor pattern 1540 may be disposed at a position corresponding to one end of the first oxide semiconductor pattern 1510 of the second pixel circuit PC2 and may correspond to a kind of dummy electrode.

Each of the first oxide semiconductor pattern 1510, the second oxide semiconductor pattern 1520, the third oxide semiconductor pattern 1530, and the fourth oxide semiconductor pattern 1540 may include at least a partially conductive region. As an example, at least a portion of each of the first oxide semiconductor pattern 1510, the second oxide semiconductor pattern 1520, the third oxide semiconductor pattern 1530, and the fourth oxide semiconductor pattern 1540 may be doped and/or plasma processed, and accordingly, the processed portion may be made conductive.

A third gate insulating layer 109 may be disposed to cover the semiconductor layer 1500. The third gate insulating layer 109 may be an inorganic insulating layer including an inorganic insulating material such as silicon oxide, silicon nitride, and/or silicon oxynitride. The second gate insulating layer 105 may have a single-layered structure or a multi-layered structure.

A third gate layer 1600 shown in FIG. 18 may be disposed on the third gate insulating layer 109. FIG. 14 shows, for convenience of description, the third gate layer 1600 and the semiconductor layer 1500 thereunder in an overlapping manner. It is shown in FIG. 18 that the third gate layer 1600 includes the first gate electrode 1610, the sixth conductive layer 1620, a seventh conductive layer 1630, the first reference gate line GRL, the scan line GWL, the second reference gate line GCL, the second emission control line EMBL, and an auxiliary power line 1640. The elements in the first pixel circuit PC1 and the elements in the second pixel circuit PC2 may be approximately symmetrical to each other with respect to the imaginary line IML between the first pixel circuit PC1 and the second pixel circuit PC2.

The first gate electrode 1610, the sixth conductive layer 1620, the seventh conductive layer 1630, the first reference gate line GRL, the scan line GWL, the second reference gate line GCL, the second emission control line EMBL, and the auxiliary power line 1640 may include aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu), and may have a single-layered structure or a multi-layered structure including these materials. However, example embodiments are not limited thereto. Elements included in the third gate layer 1600 may be simultaneously formed using the same material, and thus, may have the same layer structure.

The first gate electrode 1610 of each of the first pixel circuit PC1 and the second pixel circuit PC2 may have an isolated shape and be a gate electrode of the first transistor T1. A portion of the first oxide semiconductor pattern 1510 overlapping the first gate electrode 1610 may be a channel region C1, and two opposite sides of the channel region C1 may be conductive regions S1 and D1 made conductive by being doped with impurities or plasma-processed. One of the conductive regions S1 and D1 may be a source region and the other may be a drain region. The source region and the drain region may correspond to a source electrode and a drain electrode. The positions of the source region and the drain region may be exchanged depending on the properties of the transistor.

The sixth conductive layer 1620 disposed in each of the first pixel circuit PC1 and the second pixel circuit PC2 may have an isolated shape and be an integral body in two adjacent pixel circuits. As an example, as shown in FIG. 18, the sixth conductive layer 1620 belonging to the first pixel circuit PC1 may be an integral body with the sixth conductive layer 1620 of a pixel circuit located in the −x direction, that is, a pixel circuit located in a (j−1)-th column, and the sixth conductive layer 1620 belonging to the second pixel circuit PC2 may be an integral body with the sixth conductive layer 1620 of a pixel circuit located in the +x direction, that is, a pixel circuit located in a (j+2)-th column.

The sixth conductive layer 1620 may be a gate electrode of the fourth transistor T4. A portion of the first oxide semiconductor pattern 1510 overlapping the sixth conductive layer 1620 may be a channel region C4, and two opposite sides of the channel region C4 may be conductive regions S4 and D4 made conductive by being doped with impurities or plasma-processed. One of the conductive regions S4 and D4 may be a source region and the other may be a drain region. The source region and the drain region may correspond to a source electrode and a drain electrode. The positions of the source region and the drain region may be exchanged depending on the properties of the transistor. The sixth conductive layer 1620 may be connected to the first emission control line EML through a contact hole 1620CT formed in the second gate insulating layer 105, the first interlayer insulating layer 107, the second interlayer insulating layer 108, and the third gate insulating layer 109.

The seventh conductive layer 1630 may be located over the first pixel circuit PC1 and the second pixel circuit PC2 and have an isolated shape. The seventh conductive layer 1630 may be connected to the horizontal connection line DHL described below and may electrically connect disconnected portions of the horizontal connection line DHL. This is described below.

The first reference gate line GRL may approximately extend in the second direction (the x axis direction) to pass across the first pixel circuit PC1 and the second pixel circuit PC2. The first reference gate line GRL may pass across the pixel circuits arranged in the same row as the first pixel circuit PC1 and the second pixel circuit PC2. The first reference gate line GRL may be connected to the first conductive layer 1210 through a contact hole GRLCT formed in the second gate insulating layer 105, the first interlayer insulating layer 107, the second interlayer insulating layer 108, and the third gate insulating layer 109. A portion of the first reference gate line GRL may correspond to a third gate electrode G3, a portion of the second oxide semiconductor pattern 1520 corresponding to the first reference gate line GRL may be a channel region C3, and two opposite sides of the channel region C3 may be conductive regions S3 and D3 made conductive by being doped with impurities or plasma-processed. One of the conductive regions S3 and D3 may be a source region and the other may be a drain region. The source region and the drain region may correspond to a source electrode and a drain electrode. The positions of the source region and the drain region may be exchanged depending on the properties of the transistor.

The scan line GWL may approximately extend in the second direction (the x axis direction) to pass across the first pixel circuit PC1 and the second pixel circuit PC2. The scan line GWL may pass across the pixel circuits arranged in the same row as the first pixel circuit PC1 and the second pixel circuit PC2. A portion of the scan line GWL may correspond to a second gate electrode G2, a portion of the second oxide semiconductor pattern 1520 overlapping the scan line GWL may be a channel region C2, and two opposite sides of the channel region C2 may be conductive regions S2 and D2 made conductive by being doped with impurities or plasma-processed. One of the conductive regions S2 and D2 may be a source region and the other may be a drain region. The source region and the drain region may correspond to a source electrode and a drain electrode. The positions of the source region and the drain region may be exchanged depending on the properties of the transistor.

The second reference gate line GCL may approximately extend in the second direction (the x axis direction) to pass across the first pixel circuit PC1 and the second pixel circuit PC2. The second reference gate line GCL may pass across the pixel circuits arranged in the same row as the first pixel circuit PC1 and the second pixel circuit PC2. A portion of the second reference gate line GCL may correspond to a seventh gate electrode G7, a portion of the third oxide semiconductor pattern 1530 overlapping the second reference gate line GCL may be a channel region C7, and two opposite sides of the channel region C7 may be conductive regions S7 and D7 made conductive by being doped with impurities and/or plasma-processed. One of the conductive regions S7 and D7 may be a source region and the other may be a drain region. The source region and the drain region may correspond to a source electrode and a drain electrode. The positions of the source region and the drain region may be exchanged depending on the properties of the transistor.

The second emission control line EMBL may approximately extend in the second direction (the x axis direction) to pass across the first pixel circuit PC1 and the second pixel circuit PC2. The second emission control line EMBL may pass across the pixel circuits arranged in the same row as the first pixel circuit PC1 and the second pixel circuit PC2. The second emission control line EMBL may be connected to the fourth conductive layer 1240 through a contact hole EMBLCT formed in the second gate insulating layer 105, the first interlayer insulating layer 107, the second interlayer insulating layer 108, and the third gate insulating layer 109. A portion of the second emission control line EMBL may correspond to a sixth gate electrode G6, a portion of the first oxide semiconductor pattern 1510 overlapping the second emission control line EMBL may be a channel region C6, and two opposite sides of the channel region C6 may be conductive regions S6 and D6 made conductive by being doped with impurities and/or plasma-processed. One of the conductive regions S6 and D6 may be a source region and the other may be a drain region. The source region and the drain region may correspond to a source electrode and a drain electrode. The positions of the source region and the drain region may be exchanged depending on the properties of the transistor.

The auxiliary power line 1640 may approximately extend in the second direction (the x axis direction) to pass across the first pixel circuit PC1 and the second pixel circuit PC2. The auxiliary power line 1640 may pass across the pixel circuits arranged in the same row as the first pixel circuit PC1 and the second pixel circuit PC2. The auxiliary power line 1640 is connected to a driving voltage line PL described below, and accordingly, a set of auxiliary power lines 1640 and driving voltage lines PL may be made to have a mesh structure in the display area DA.

A third interlayer insulating layer 111 may be disposed to cover the third gate layer 1600. The third interlayer insulating layer 111 may be an inorganic insulating layer including an inorganic insulating material such as silicon oxide, silicon nitride, and/or silicon oxynitride. The third interlayer insulating layer 111 may have a single-layered structure or a multi-layered structure. As an example, the third interlayer insulating layer 111 may have a stack structure of a layer including silicon oxide and a layer including silicon nitride. The third interlayer insulating layer 111 may be an organic insulating layer including an organic insulating material such as acryl, benzocyclobutene (BCB), polyimide, or hexamethyldisiloxane (HMDSO).

A first source drain layer 1700 shown in FIG. 19 may be disposed on the third interlayer insulating layer 111. It is shown in FIG. 19 that the first source drain layer 1700 includes the driving voltage line PL, a first connection electrode 1720, a second connection electrode 1730, a third connection electrode 1740, a fourth connection electrode 1750, a fifth connection electrode 1760, a sixth connection electrode 1772, a seventh connection electrode 1774, an eighth connection electrode 1776, a dummy connection electrode 1776′, and the horizontal connection line DHL. The elements in the first pixel circuit PC1 and the elements in the second pixel circuit PC2 may be approximately symmetrical to each other with respect to the imaginary line IML between the first pixel circuit PC1 and the second pixel circuit PC2.

The driving voltage line PL, the first connection electrode 1720, the second connection electrode 1730, the third connection electrode 1740, the fourth connection electrode 1750, the fifth connection electrode 1760, the sixth connection electrode 1772, the seventh connection electrode 1774, the eighth connection electrode 1776, and the horizontal connection line DHL may include aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu), and may have a single-layered structure or multi-layered structure including these materials. However, example embodiments are not limited thereto. Elements included in the first source drain layer 1700 may be simultaneously formed using the same material, and thus, may have the same layer structure.

The driving voltage line PL may have a shape extending in the first direction (the y axis direction) along the imaginary line IML between the first pixel circuit PC1 and the second pixel circuit PC2. The driving voltage line PL may be connected to the auxiliary power line 1640 through a contact hole PLCT1 formed in the third interlayer insulating layer 111 thereunder. Through this connection structure, the plurality of driving voltage lines PL and the plurality of auxiliary power lines 1640 may form a mesh structure in the display area DA, and through this, a voltage drop (IR drop) of the driving voltage ELVDD may be reduced (and/or minimized). Meanwhile, the driving voltage line PL may be connected to the silicon semiconductor layer 1110 through a contact hole PLCT2 formed in the first gate insulating layer 103, the second gate insulating layer 105, the first interlayer insulating layer 107, the second interlayer insulating layer 108, the third gate insulating layer 109, and the third interlayer insulating layer 111. Through this, the silicon semiconductor layer 1110 may be made to have an electrical potential equal or similar to the driving voltage ELVDD.

The first connection electrode 1720 disposed in each of the first pixel circuit PC1 and the second pixel circuit PC2 may have an isolated shape. The first connection electrode 1720 may be electrically connected to the first semiconductor layer A1 of the first transistor T1 through a contact hole 1720CT1 formed in the third gate insulating layer 109 and the third interlayer insulating layer 111. In addition, the first connection electrode 1720 may be connected to the fifth semiconductor layer A5 of the fifth transistor T5 through a contact hole 1720CT2 formed in the first gate insulating layer 103, the second gate insulating layer 105, the first interlayer insulating layer 107, the second interlayer insulating layer 108, the third gate insulating layer 109, and the third interlayer insulating layer 111. Accordingly, the first connection electrode 1720 may electrically connect the first transistor T1 and the fifth transistor T5 to each other.

The second connection electrode 1730 disposed in each of the first pixel circuit PC1 and the second pixel circuit PC2 may have an isolated shape. The second connection electrode 1730 may correspond to the first node N1 in the pixel circuit of FIG. 10. The second connection electrode 1730 may be electrically connected to the first gate electrode 1610 of the first transistor T1 through a contact hole 1730CT3 formed in the third interlayer insulating layer 111. In addition, the second connection electrode 1730 may be electrically connected to the third semiconductor layer A3 through a contact hole 1730CT1 formed in the third gate insulating layer 109 and the third interlayer insulating layer 111. In addition, the second connection electrode 1730 passes through an opening formed in the fifth conductive layer 1310 through a contact hole 1730CT2 formed in the second gate insulating layer 105, the first interlayer insulating layer 107, the second interlayer insulating layer 108, the third gate insulating layer 109, and the third interlayer insulating layer 111, and be electrically connected to the third conductive layer 1230. Accordingly, the second connection electrode 1730 may electrically connect the first gate electrode G1 of the first transistor T1, the third transistor T3, and the first storage electrode CEs1 to each other.

The third connection electrode 1740 disposed in each of the first pixel circuit PC1 and the second pixel circuit PC2 may have an isolated shape. The third connection electrode 1740 may correspond to the second node N2 in the pixel circuit of FIG. 10. The third connection electrode 1740 may be electrically connected to the fifth conductive layer 1310 including the second storage electrode CEs2 and the second hold electrode CEh2 through a contact hole 1740CT1 formed in the first interlayer insulating layer 107, the second interlayer insulating layer 108, the third gate insulating layer 109, and the third interlayer insulating layer 111. In addition, the third connection electrode 1740 may be electrically connected to the first oxide semiconductor pattern 1510 through a contact hole 1740CT2 formed in the third gate insulating layer 109 and the third interlayer insulating layer 111. A connection point of the third connection electrode 1740 and the first oxide semiconductor pattern 1510 may be located between a region of the first oxide semiconductor pattern 1510 corresponding to the first semiconductor layer A1 and a region of the first oxide semiconductor pattern 1510 corresponding to the sixth semiconductor layer A6 (FIG. 17). Through this, the third connection electrode 1740 may electrically connect the second storage electrode CEs2, the second hold electrode CEh2, the first transistor T1, and the sixth transistor T6 to each other.

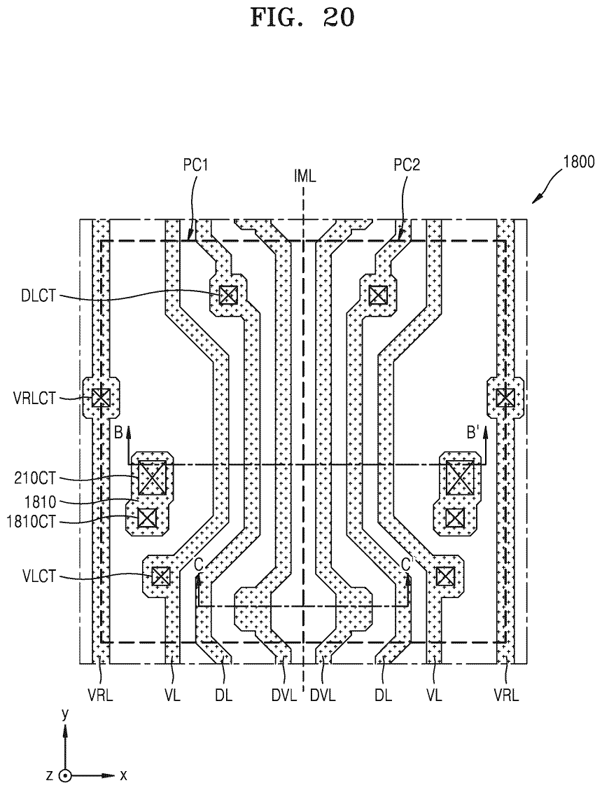

The fourth connection electrode 1750 located in each of the first pixel circuit PC1 and the second pixel circuit PC2 has an isolated shape, and may be an integral body in the first pixel circuit PC1 and a pixel circuit located in a (j−1)-th column, and also, be an integral body in the second pixel circuit PC2 and a pixel circuit located in a (j+2)-th column. The fourth connection electrode 1750 may be electrically connected to the third semiconductor layer A3 through a contact hole 1750CT1 formed in the third gate insulating layer 109 and the third interlayer insulating layer 111. In addition, the fourth connection electrode 1750 may be electrically connected to the seventh semiconductor layer A7 through a contact hole 1750CT2 formed in the third gate insulating layer 109 and the third interlayer insulating layer 111. The fourth connection electrode 1750 may be electrically connected to the reference voltage line VRL (FIG. 20) described below and may transfer the reference voltage VREF to the third transistor T3 and the seventh transistor T7.

The fifth connection electrode 1760 disposed in each of the first pixel circuit PC1 and the second pixel circuit PC2 may have an isolated shape. In addition, the fifth connection electrode 1760 may be electrically connected to the second conductive layer 1220, which is the first hold electrode CEh1 of the hold capacitor Chd through a contact hole 1760CT1 formed in the second gate insulating layer 105, the first interlayer insulating layer 107, the second interlayer insulating layer 108, the third gate insulating layer 109, and the third interlayer insulating layer 111. In addition, the fifth connection electrode 1760 may be electrically connected to the seventh semiconductor layer A7 through a contact hole 1760CT2 formed in the third gate insulating layer 109 and the third interlayer insulating layer 111. Through this, the fifth connection electrode 1760 may electrically connect the first hold electrode CEh1 and the seventh transistor T7 to each other.

The sixth connection electrode 1772 disposed in each of the first pixel circuit PC1 and the second pixel circuit PC2 may have an isolated shape. The sixth connection electrode 1772 may be electrically connected to the second semiconductor layer A2 through a contact hole 1772CT formed in the third gate insulating layer 109 and the third interlayer insulating layer 111. The sixth connection electrode 1772 may be electrically connected to the data line DL (FIG. 20) to transfer a data signal DATA to the second transistor T2.

The seventh connection electrode 1774 disposed in each of the first pixel circuit PC1 and the second pixel circuit PC2 may have an isolated shape. The seventh connection electrode 1774 may be electrically connected to the fourth semiconductor layer A4 of the fourth transistor T4 through a contact hole 1774CT formed in the third gate insulating layer 109 and the third interlayer insulating layer 111. The seventh connection electrode 1774 may be electrically connected to a pixel electrode 210 of the light-emitting diode LED as described below.

The eighth connection electrode 1776 located in the second pixel circuit PC2 may have an isolated shape. In the second pixel circuit PC2, the eighth connection electrode 1776 may be electrically connected to the fourth semiconductor layer A4 of the fourth transistor T4 through a contact hole 1776CT formed in the third gate insulating layer 109 and the third interlayer insulating layer 111. As described below, the eighth connection electrode 1776 may be electrically connected to the initialization voltage line VL (FIG. 20) passing across the second pixel circuit PC2 to transfer the initialization voltage VINT to the fourth transistor T4. For reference, the fourth transistor T4 located in the first pixel circuit PC1 located in a j-th column is electrically connected to a fourth transistor of a pixel circuit located in a (j−1)-th column (adjacent in the −x direction) as shown in FIG. 17. Accordingly, the fourth transistor T4 located in the first pixel circuit PC1 may be electrically connected to an initialization voltage line (not shown) passing across a pixel circuit located in a (j−1)-th column (adjacent in the −x direction) instead of the initialization voltage line VL (FIG. 20) passing across the first pixel circuit PC1.

The dummy connection electrode 1776′ located in the first pixel circuit PC1 may have an isolated shape. The dummy connection electrode 1776′ may be electrically connected to the fourth oxide semiconductor pattern 1540, which is also a dummy pattern, through a contact hole 1776CT′. For reference, the dummy connection electrode 1776′ and the eighth connection electrode 1776 may be symmetrical to each other with respect to the imaginary line IML.

Referring to FIGS. 18, 19, and 23 together, the horizontal connection lines DHL extending approximately in the second direction (the x axis direction) but disconnected by the driving voltage line PL (that is, the conductive line) may be electrically connected to the seventh conductive layer 1630 through contact holes DHLCT formed in the third interlayer insulating layer 111. Accordingly, a set of the seventh conductive layer 1630 and the horizontal connection line DHL may correspond to a portion of the data transfer line DTL described with reference to FIG. 8 or 9, for example, one of the first horizontal connection line DHL1, the second horizontal connection line DHL2, and the third horizontal connection line DHL3. In some example embodiments, the horizontal connection line DHL is electrically connected to the vertical connection line DVL (see FIG. 20) described below, the horizontal connection line DHL may be electrically connected to the vertical connection line DVL at a portion where the contact hole DHLCT is located.

The horizontal connection line DHL may be defined as a portion of the data transfer line DTL electrically connected to the seventh conductive layer 1630 and extending in the second direction (the x axis direction). That is, the seventh conductive layer 1630 may be a portion of the horizontal connection line DHL. When defining this again, the horizontal connection line DHL may include a first connection portion CP1 and a second connection portion CP2 (that is, the seventh conductive layer 1630), and the first connection portion CP1 and the second connection portion CP2 may be disposed on layers of different levels and electrically connected to each other. Because the second connection portion CP2 is disposed on the third gate insulating layer 109, and the first connection portion CP1 is disposed on the third interlayer insulating layer 111, a vertical distance h1 from the upper surface of the substrate 10 to the second connection portion CP2 in a third direction (a z axis direction) may be less than a vertical distance h2 from the upper surface of the substrate 10 to the first connection portion CP1.

Like this, the first connection portion CP1 and the second connection portion CP2 are disposed on layers of different levels, the first connection portion CP1 may include a first conductive material, and the second connection portion CP2 may include a second conductive material. A resistance of the first conductive material may be less than a resistance of the second conductive material. Accordingly, the resistance of the first connection portion CP1 may be less than the resistance of the second connection portion CP2, and for example, the resistance of the first connection portion CP1 may be about ⅓ of the resistance of the second connection portion CP2.

The driving voltage line PL may be disposed on the third interlayer insulating layer 111, and the second connection portion CP2 (that is, the seventh conductive layer 1630) may be disposed on the third gate insulating layer 109. Accordingly, the second connection portion CP2 (that is, the seventh conductive layer 1630) may at least partially overlap the driving voltage line PL described with reference to FIG. 19. Through this structure, because the driving voltage line PL may be implemented using a wiring including a conductive layer of an integral type approximately in the first direction (the y axis direction) as shown in FIG. 19, a resistance thereof is reduced, and accordingly, the occurrence of an issue such as an IR drop may be reduced.

Although it is shown in FIG. 18 that the second connection portion CP2 (that is, the seventh conductive layer 1630) of the horizontal connection line DHL is disposed on the third interlayer insulating layer 111, the disclosure is not necessarily limited thereto. The second connection portion CP2 of the horizontal connection line DHL may be disposed on a layer of the same level as the bottom metal layer 1010, the first gate layer 1200, the second gate layer 1300, and the intermediate conductive layer 1400 described with reference to FIGS. 12, 14 to 16.

Like this, a fourth interlayer insulating layer 113 may be disposed on the first source drain layer 1700 described with reference to FIG. 19. The fourth interlayer insulating layer 113 may be an inorganic insulating layer including an inorganic insulating material such as silicon oxide, silicon nitride, and/or silicon oxynitride. However, example embodiments are not limited thereto. The fourth interlayer insulating layer 113 may have a single-layered structure or a multi-layered structure. As an example, the fourth interlayer insulating layer 113 may have a stack structure of a layer including silicon oxide and a layer including silicon nitride. The fourth interlayer insulating layer 113 may be an organic insulating layer including an organic insulating material such as acryl, benzocyclobutene (BCB), polyimide, or hexamethyldisiloxane (HMDSO). However, example embodiments are not limited thereto.

A second source drain layer 1800 shown in FIG. 20 may be disposed on the fourth interlayer insulating layer 113. It is shown in FIG. 20 that the second source drain layer 1800 includes the data line DL, the vertical connection line DVL, the initialization voltage line VL, the reference voltage line VRL, and a ninth connection electrode 1810. The elements in the first pixel circuit PC1 and the elements in the second pixel circuit PC2 may be approximately symmetrical to each other with respect to the imaginary line IML between the first pixel circuit PC1 and the second pixel circuit PC2.

Each of the data line DL, the vertical connection line DVL, the initialization voltage line VL, and the reference voltage line VRL may extend in the first direction (the y axis direction). The data line DL, the vertical connection line DVL, the initialization voltage line VL, and the reference voltage line VRL passing across the first pixel circuit PC1, and the data line DL, the vertical connection line DVL, the initialization voltage line VL, and the reference voltage line VRL passing across the second pixel circuit PC2 may be substantially symmetrical to each other with respect to the imaginary line IML.

The data line DL passing across each of the first pixel circuit PC1 and the second pixel circuit PC2 may be electrically connected to the sixth connection electrode 1772 described with reference to FIG. 19 through a contact hole DLCT formed in the fourth interlayer insulating layer 113 to provide data signals to the second transistor T2.

The vertical connection line DVL passing across each of the first pixel circuit PC1 and the second pixel circuit PC2 may correspond to a portion of the data transfer line DTL described with reference to FIG. 8 or 9, for example, one of the first vertical connection line DVL1, the second vertical connection line DVL2, the third vertical connection line DVL3, the first additional vertical connection line DVL1′, the second additional vertical connection line DVL2′, and the third additional vertical connection line DVL3′. Because the vertical connection line DVL includes a portion protruding in the second direction (the x axis direction), in some example embodiments the vertical connection line DVL is electrically connected to the horizontal connection line DHL located thereunder, the vertical connection line DVL may be electrically connected to the horizontal connection line DHL through a contact hole formed in the fourth interlayer insulating layer 113 in the protruded portion.

The initialization voltage line VL passing across the second pixel circuit PC2 may be electrically connected to the eighth connection electrode 1776 thereunder through a contact hole VLCT formed in the fourth interlayer insulating layer 113, and the eighth connection electrode 1776 may be electrically connected to the first oxide semiconductor pattern 1510 thereunder through a contact hole 1776CT to transfer the initialization voltage to the fourth transistor T4 of the second pixel circuit PC2.

The initialization voltage line VL passing across the first pixel circuit PC1 may be electrically connected to the dummy connection electrode 1776′ through the contact hole VLCT formed in the fourth interlayer insulating layer 113. As described above with reference to FIG. 19, the fourth transistor T4 located in the first pixel circuit PC1 located in a j-th column is electrically connected to a fourth transistor of a pixel circuit located in a (j−1)-th column (adjacent in the −x direction) as shown in FIG. 17. Accordingly, the fourth transistor T4 located in the first pixel circuit PC1 may be electrically connected to an initialization voltage line (not shown) passing across a pixel circuit located in a (j−1)-th column (adjacent in the −x direction) instead of the first initialization voltage line VL passing across the first pixel circuit PC1.

In some example embodiments, the semiconductor layer 1500 is made to be symmetrical with respect to the imaginary line IML in the first pixel circuit PC1 and the second pixel circuit PC2, and accordingly, the fourth oxide semiconductor pattern 1540 of the first pixel circuit PC1 may be made to be an integral body with the first oxide semiconductor pattern 1510. In this case, the initialization voltage line VL passing across the first pixel circuit PC1 may be made to be electrically connected to the fourth transistor T4 of the first pixel circuit PC1.

The reference voltage line VRL passing across each of the first pixel circuit PC1 and the second pixel circuit PC2 may be electrically connected to the fourth connection electrode 1750 described with reference to FIG. 19 through a contact hole VRLCT formed in the fourth interlayer insulating layer 113. As described above, the fourth connection electrode 1750 may be electrically connected to the second oxide semiconductor pattern 1520 and the third oxide semiconductor pattern 1530 to provide the reference voltage to the third transistor T3 and the seventh transistor T7.

For reference, the first pixel circuit PC1 located in a j-th column may share the reference voltage line VRL with a pixel circuit located in a (j−1)-th column adjacent in the −x direction, and the second pixel circuit PC2 located in a (j+1)-th column may share the reference voltage line VRL with a pixel circuit located in a (j+2)-th column adjacent in the +x direction.

Each ninth connection electrode 1810 may have an isolated shape. The ninth connection electrode 1810 located in each of the first pixel circuit PC1 and the second pixel circuit PC2 may be electrically connected to the seventh connection electrode 1774 described with reference to FIG. 19 through a contact hole 1810CT formed in the fourth interlayer insulating layer 113. The ninth connection electrode 1810 may be also electrically connected to the pixel electrode 210 in the upper portion through a contact hole 210CT in the upper portion. As described above, the seventh connection electrode 1774 may be electrically connected to the fourth transistor T4 and the sixth transistor T6. Accordingly, the seventh connection electrode 1774 and the ninth connection electrode 1810 may electrically connect the pixel electrode of the light-emitting diode LED to the fourth transistor T4 and the sixth transistor T6.

A planarization layer 115 may be disposed to cover the second source drain layer 1800. The planarization layer 115 may be an organic insulating layer including an organic insulating material such as acryl, benzocyclobutene (BCB), polyimide, or hexamethyldisiloxane (HMDSO). However, example embodiments are not limited thereto.

The light-emitting diode LED may be disposed on the planarization layer 115. The light-emitting diode LED may include the pixel electrode 210 on the planarization layer 115, an intermediate layer 220, and a common electrode 230. It is shown in FIG. 21 that the pixel electrodes 210 are disposed. For reference, because the light-emitting diode includes the pixel electrode 210, the position of the pixel electrode 210 may be referred to as the position of the light-emitting diode. FIG. 21 shows, for convenience, the pixel electrodes 210 and the second source drain layer 1800 thereunder in an overlapping manner.

As shown in FIG. 21, the light-emitting diodes LED may be disposed apart from each other. It is shown in FIG. 21 that a second light-emitting diode LED2 overlapping the first pixel circuit PC1 and the second pixel circuit PC2 is electrically connected to a first pixel circuit PC1 located in an i-th row and a j-th column. Like this, although the second light-emitting diode LED2 may be located on the imaginary line IML between the first pixel circuit PC1 and the second pixel circuit PC2, as shown in FIG. 21, the pixel electrode 210 of the second light-emitting diode LED2 may have a protrusion protruding in the −x direction and be electrically connected to the first pixel circuit PC1 through the contact hole 210CT formed in the planarization layer 115. In also other light-emitting diodes, the pixel electrode 210 may have a protrusion and be electrically connected to a corresponding pixel circuit through a contact hole 210CT thereunder in the protrusion.

Four third light-emitting diodes LED3 may be disposed around the second light-emitting diode LED2. It is shown in FIG. 21 that, in dotted lines of a quadrangular shape representing a boundary of a set of the first pixel circuit PC1 and the second pixel circuit PC2, the third light-emitting diodes LED3 are located at four vertexes of the quadrangle. That is, it is shown in FIG. 21 that a third light-emitting diode LED3 located at the lower right end is electrically connected to the second pixel circuit PC2 located in an i-th row and a (j+1)-th column, a third light-emitting diode LED3 located at the upper right end is electrically connected to a pixel circuit located in an (i−1)-th row and a (j+1)-th column and adjacent to the second pixel circuit PC2 in the +y direction, a third light-emitting diode LED3 located at the lower left end is electrically connected to a pixel circuit located in an i-th row and a (j-1)-th column and adjacent to the first pixel circuit PC1 in the −x direction, and a third light-emitting diode LED3 located at the upper left end is electrically connected to a pixel circuit located in an (i−1)-th row and a (j−1)-th column.

For reference, a first light-emitting diode not shown may be electrically connected to a pixel circuit adjacent to the first pixel circuit PC1 in the +y direction and located an (i−1)-th row and a j-th column. In addition, first light-emitting diodes may be electrically connected to a pixel circuit adjacent to the second pixel circuit PC2 in the +x direction and located in an i-th row and a (j+2)-th column, a pixel circuit located in an i-th row and a (j−2)-th column, and a pixel circuit adjacent to the first pixel circuit PC1 in the −y direction and located in an (i+1)-th row and a j-th column. Similarly to the second light-emitting diode LED2, even in a case of the first light-emitting diode, four third light-emitting diodes LED3 may be disposed around the first light-emitting diode.

Like this, pixel circuits arranged in the +x direction in an i-th row may be a case in which a set of a pixel circuit for a first light-emitting diode, a pixel circuit for a third light-emitting diode LED3, a pixel circuit for a second light-emitting diode LED2, and a pixel circuit for a third light-emitting diode LED3 is repeated. In addition, pixel circuits arranged in the y axis direction in a j-th column may be a case in which a set of a pixel circuit for a first light-emitting diode and a pixel circuit for a second light-emitting diode LED2 is repeated, and pixel circuits arranged in the first direction (the y axis direction) in each of a (j−1)-th column and a (j+1)-th column may be pixel circuits for a third light-emitting diode LED3.

As an example, a first light-emitting diode may be a diode emitting red light, a second light-emitting diode LED2 may be a diode emitting blue light, and a third light-emitting diode LED3 may be a diode emitting green light.

However, the arrangement of the light-emitting diodes is not limited to the above arrangement and may be variously modified.

The pixel electrode 210 may be a (semi) light-transmissive electrode or a reflective electrode. As an example, the pixel electrode 210 may include a reflective layer and a transparent or semi-transparent electrode layer on the reflective layer, wherein the reflective layer includes Ag, Mg, Al, Pt, Pd, Au, Ni, Nd, Ir, Cr, or compound thereof. However, example embodiments are not limited thereto. The transparent or semi-transparent electrode layer may include at least one of indium tin oxide (ITO), indium zinc oxide (IZO), zinc oxide (ZnOX:ZnO or ZnO2), indium oxide (In2O3), indium gallium oxide (IGO), or aluminum zinc oxide (AZO). As an example, the pixel electrode 210 may have a three-layered structure of ITO/Ag/ITO.

A pixel-defining layer 119 may be disposed on the planarization layer 115. The pixel-defining layer 119 may reduce and/or prevent arcs and the like from occurring at the edge of the pixel electrode 210 by covering the edge of the pixel electrode 210 and increasing a distance between the pixel electrode 210 and the common electrode 230 over pixel electrode 210. That is, as shown in FIGS. 21 and 22, the pixel-defining layer 119 has an opening 119OP to expose the central portion of the pixel electrode 210. The exposed portion of the pixel electrode 210 may be defined as an emission area EA. The pixel-defining layer 119 may include an organic insulating material such as polyimide, an acrylic resin, benzocyclobutene, a phenolic resin, and the like and be formed by using spin coating and the like.

At least a portion of the intermediate layer 220 including an emission layer of the light-emitting diode LED may be disposed in the opening formed in the pixel-defining layer 119. The emission area of the light-emitting diode LED may be defined by the opening. The intermediate layer 220 may include the emission layer. The emission layer may include an organic material including a fluorescent or phosphorous material emitting red, green, blue, or white light. The emission layer may include a polymer organic material or a low molecular weight organic material. Functional layers may be selectively further disposed under and on the emission layer, the functional layers including a hole transport layer (HTL), a hole injection layer (HIL), an electron transport layer (ETL), and an electron injection layer (EIL).

Alternatively, the intermediate layer 220 may include a first stack including the emission layer and the functional layer, a second stack including the emission layer and the functional layer, and a charge generation layer between the first stack and the second stack. The charge generation layer may include a negative charge generation layer and a positive charge generation layer. A light-emission efficiency of a tandem type light-emitting diode LED including the plurality of emission layers, may be enhanced even more by the negative charge generation layer and the positive charge generation layer.

The negative charge generation layer may be an n-type charge generation layer. The negative charge generation layer may supply electrons. The negative charge generation layer may include hosts and dopants. The host may include an organic material. The dopant may include a metal material. The positive charge generation layer may be a p-type charge generation layer. The positive charge generation layer may supply holes. The positive charge generation layer may include hosts and dopants. The host may include an organic material. The dopant may include a metal material.

The emission layer may have a shape patterned to correspond to the pixel electrode 210. Layers of the intermediate layer other than the emission layer may be an integral body over the plurality of pixel electrodes 210. However, various modifications may be made.

The common electrode 230 may be a light-transmissive electrode or a reflective electrode. As an example, the common electrode 230 may be a transparent or semi-transparent electrode and may include a metal thin film including Li, Ca, Al, Ag, Mg, or compound (e.g., LiF) thereof and having a small work function. In addition, the common electrode 230 may further include a transparent conductive oxide (TCO) layer such as ITO, indium zinc oxide (IZO), ZnO, ZnO₂, or In₂O₃ disposed on the metal thin film. However, example embodiments are not limited thereto.

The common electrode 230 may be integrally formed over the entire surface of the display area DA to cover the display area DA and be disposed on the intermediate layer 220 and the pixel-defining layer 119. That is, each of the pixel electrodes 210 may be disposed to correspond to each light-emitting diode, and the common electrode 230 may be an integral body to correspond to the plurality of light-emitting diodes LED. The plurality of light-emitting diodes LED may share the common electrode 230. A stack structure of the pixel electrode 210, the intermediate layer 220, and the common electrode 230 may correspond to the light-emitting diode LED.

In some example embodiments, an encapsulation layer may be disposed on the light-emitting diode LED. The encapsulation layer may include a first inorganic encapsulation layer, a second inorganic encapsulation layer, and an organic encapsulation layer therebetween.

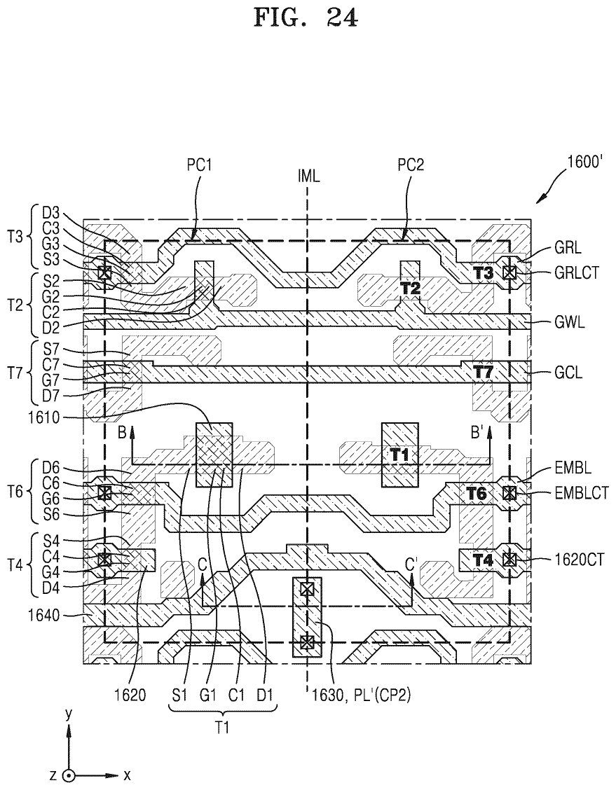

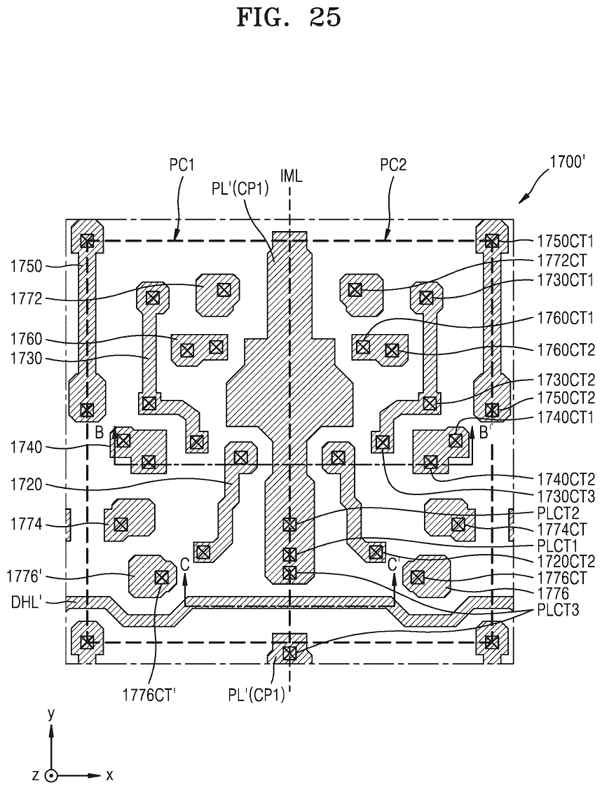

FIGS. 24 to 25 are schematic arrangement views of elements such as transistors and a capacitor, for each layer, of a display panel according to some example embodiments. A third gate layer 1600′ of FIG. 24 is a modification of the third gate layer 1600 shown in FIG. 18, and a first source drain layer 1700′ of FIG. 25 is a modification of the first source drain layer 1700 shown in FIG. 19. In addition, the remaining elements for each layer included in the first pixel circuit PC1 and the second pixel circuit PC2 are the same as the arrangement views of remaining FIGS. 12 to 17, and 20 except for FIGS. 18 and 19.

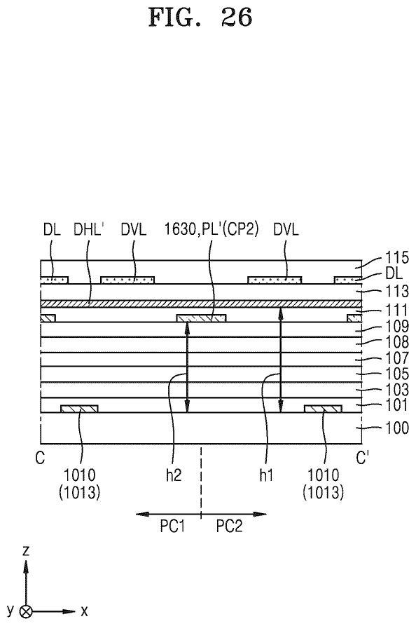

In addition, FIG. 26 is a schematic cross-sectional view of the display panel taken along line C-C′ of FIGS. 24 and 25. FIG. 26 is a modification of FIG. 23, shows a cross-section taken along line C-C′ of FIGS. 12 to 20, and includes FIGS. 24 and 25 instead of FIGS. 18 and 19. Referring to FIG. 24, the third gate layer 1600 may include the first gate electrode 1610, the sixth conductive layer 1620, the seventh conductive layer 1630′, the first reference gate line GRL, the scan line GWL, the second reference gate line GCL, the second emission control line EMBL, and the auxiliary power line 1640. In FIG. 24, the remaining elements except for the seventh conductive layer 1630′, for example, the first gate electrode 1610, the sixth conductive layer 1620, the first reference gate line GRL, the scan line GWL, the second reference gate line GCL, the second emission control line EMBL, and the auxiliary power line 1640 are the same as those described with reference to FIG. 18, descriptions thereof are omitted.

The seventh conductive layer 1630′ may extend in the first direction (the y axis direction). The seventh conductive layer 1630′ may be located over the first pixel circuit PC1 and the second pixel circuit PC2 and have an isolated shape. The seventh conductive layer 1630′ may be connected to a driving voltage line PL′ described below and may electrically connect disconnected portions of the driving voltage line PL′.

It is shown in FIG. 25 that the first source drain layer 1700′ includes the driving voltage line PL′, the first connection electrode 1720, the second connection electrode 1730, the third connection electrode 1740, the fourth connection electrode 1750, the fifth connection electrode 1760, the sixth connection electrode 1772, the seventh connection electrode 1774, the eighth connection electrode 1776, a dummy connection electrode 1776′, and a horizontal connection line DHL′. In FIG. 25, the remaining elements except for the configuration of the driving voltage line PL′ and the horizontal connection line DHL′, for example, the first connection electrode 1720, the second connection electrode 1730, the third connection electrode 1740, the fourth connection electrode 1750, the fifth connection electrode 1760, the sixth connection electrode 1772, the seventh connection electrode 1774, the eighth connection electrode 1776, a dummy connection electrode 1776′ are the same as those described with reference to FIG. 19, descriptions thereof are omitted.

The driving voltage line PL′ is electrically connected to the seventh conductive layer 1630′ of FIG. 24 and may be defined as a portion of the driving voltage line PL′ extending in the first direction (the y axis direction). That is, the seventh conductive layer 1630′ may be a portion of the driving voltage line PL′. When defining this again, the driving voltage line PL′ may include a first connection portion CP1 and a second connection portion CP2 (that is, the seventh conductive layer 1630′), and the first connection portion CP1 and the second connection portion CP2 may be disposed on layers of different levels and electrically connected to each other. The second connection portion CP2 of the driving voltage line PL′ may overlap the horizontal connection line DHL′ in at least a partial region.

As shown in FIG. 26, because the second connection portion CP2 is disposed on the third gate insulating layer 109, and the first connection portion CP1 is disposed on the third interlayer insulating layer 111, a vertical distance h1 from the upper surface of the substrate 10 to the second connection portion CP2 in a third direction (a z axis direction) may be less than a vertical distance h2 from the upper surface of the substrate 10 to the first connection portion CP1.

Like this, the first connection portion CP1 and the second connection portion CP2 are disposed on layers of different levels, the first connection portion CP1 may include a first conductive material, and the second connection portion CP2 may include a second conductive material. A resistance of the first conductive material may be less than a resistance of the second conductive material. Accordingly, the resistance of the first connection portion CP1 may be less than the resistance of the second connection portion CP2, and for example, the resistance of the first connection portion CP1 may be about ⅓ of the resistance of the second connection portion CP2.

As described above, because a partial region of the driving voltage line PL′, that is, the second connection portion CP2 is disposed on a layer of a different level from the horizontal connection line DHL′, the horizontal connection line DHL′ may be provided as an integral conductive layer continuously extending in the second direction (the x axis direction). In other words, it may mean that the horizontal connection line DHL′ includes only an integral conductive layer disposed on a layer of the same level without being in contact with a conductive layer disposed on a layer of a different level in at least the display area DA (see FIG. 7). The horizontal connection line DHL′ may have a relatively lower resistance compared to a wiring including a contact with a conductive layer disposed on a layer of a different level. Accordingly, the horizontal connection line DHL′ may secure a charging time of the data line DL and/or have a characteristic advantageous for high-speed driving.

Although it is shown in FIGS. 24 to 26 that the second connection portion CP2 (that is, the seventh conductive layer 1630′) of the driving voltage line PL′ is disposed on the third interlayer insulating layer 111, the disclosure is not necessarily limited thereto. The second connection portion CP2 of the driving voltage line PL′ may be disposed on a layer of the same level as the bottom metal layer 1010, the first gate layer 1200, the second gate layer 1300, and the intermediate conductive layer 1400 described with reference to FIGS. 12, 14 to 16.

In addition, although it is shown in FIGS. 24 to 26 that the driving voltage line PL includes the first connection portion CP1 and the second connection portion CP2 disposed on different layers from each other, as an example, the disclosure is not necessarily limited thereto. The above structure is equally applicable to other wirings extending in the first direction (the y axis direction), for example, the initialization voltage line VL (see FIG. 2), the reference voltage line VRL (see FIG. 2), the common voltage line (not shown), and the like.

Up to this point, various electronic devices 1, the display panel 10, and/or the display module 11 have been described, and each of the electronic devices 1, the display panel 10, and/or the display module 11 fall within the scope of the present example embodiments.

According to some example embodiments, a display panel with improved power consumption and/or improved capability of providing high-quality images may be provided. Furthermore, an electronic device including the same may be provided. The above effect is an example, and the effects of the example embodiments are not limited thereto.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

It should be understood that example embodiments described herein should be considered in a descriptive sense only and not for purposes of limitation. Descriptions of features or aspects within each example embodiment should typically be considered as available for other similar features or aspects in other embodiments. While one or more example embodiments have been described with reference to the figures, it will be understood by those of ordinary skill in the art that various changes in form and details may be made therein without departing from the spirit and scope as defined by the following claims.

What is claimed is:

1. A display panel comprising:
a substrate including a display area and a peripheral area outside the display area;
a first pixel and a second pixel are disposed in the display area;
a first data line electrically connected to the first pixel in a first direction;
a second data line electrically connected to the second pixel in the first direction;
a conductive line electrically connected to at least one of the first pixel and the second pixel in the first direction, the conductive line configured to transfer at least one of a signal or a voltage; and
a data transfer line including a horizontal connection line electrically connected to the second data line,
wherein
at least a portion of the horizontal connection line extends in a second direction, the second direction crossing the first direction,
at least one of the horizontal connection line or the conductive line includes a first connection portion and a second connection portion electrically connected to the first connection portion, and
the at least one of the horizontal connection line or the conductive line is on a layer at a level different from a level of the first connection portion.

2. The display panel of claim 1, wherein
the horizontal connection line includes the first connection portion and the second connection portion, and
the second connection portion at least partially overlaps the conductive line.

3. The display panel of claim 2, wherein the conductive line includes a conductive layer at a same level as a level of the conductive line.

4. The display panel of claim 1, wherein
the conductive line includes the first connection portion and the second connection portion, and
the second connection portion at least partially overlaps the horizontal connection line.

5. The display panel of claim 4, wherein the horizontal connection line includes a conductive layer at a same level as a level of the horizontal connection line.

6. The display panel of claim 1, wherein a vertical distance from an upper surface of the substrate to the second connection portion in a vertical direction is less than a vertical distance from the upper surface of the substrate to the first connection portion in the vertical direction, the vertical direction being perpendicular to the substrate.

7. The display panel of claim 1, wherein the first connection portion includes a first conductive material, and the second connection portion includes a second conductive material, the second conductive material being different from the first conductive material.

8. The display panel of claim 7, wherein a resistance of the first connection portion is less than a resistance of the second connection portion.

9. The display panel of claim 1, wherein the horizontal connection line is directly connected to the second data line through a contact hole.

10. The display panel of claim 1, wherein the data transfer line further includes a first vertical connection line extending in the first direction, and the first vertical connection line is electrically connected to the horizontal connection line through a contact hole.

11. The display panel of claim 10, wherein
the data transfer line further includes a second vertical connection line extending in the first direction and spaced apart from the first vertical connection line, and
a first side of the horizontal connection line is connected to the first vertical connection line, and a second side of the horizontal connection line is connected to the second vertical connection line.

12. The display panel of claim 1, wherein the second pixel is closer to the peripheral area than the first pixel.

13. The display panel of claim 1, wherein the conductive line is a driving voltage line.

14. The display panel of claim 1, further comprising:
a first transistor on the substrate, the first transistor including a first semiconductor layer and a first gate electrode, the first gate electrode overlapping and above the first semiconductor layer in a vertical direction, the vertical direction being perpendicular to the substrate,
wherein the first semiconductor layer includes an oxide semiconductor.

15. The display panel of claim 14, further comprising a silicon semiconductor layer between the substrate and the first semiconductor layer.

16. An electronic device comprising:
a display panel; and
a lower cover defining an exterior of the electronic device, the lower cover including an opening exposing a portion of the display panel,
wherein the display panel includes
a substrate including a display area and a peripheral area outside the display area;
a first pixel and a second pixel are disposed in the display area;
a first data line electrically connected to the first pixel in a first direction,
a second data line electrically connected to the second pixel in the first direction,
a conductive line electrically connected to at least one of the first pixel and the second pixel in the first direction, the conductive line configured to transfer at least one of a signal or a voltage, and
a data transfer line including a horizontal connection line electrically connected to the second data line,
wherein
at least a portion of the horizontal connection line extends in a second direction, the second direction crossing the first direction,
at least one of the horizontal connection line or the conductive line includes a first connection portion and a second connection portion electrically connected to the first connection portion, and
the at least one of the horizontal connection line or the conductive line is on a layer at a level different from a level of the first connection portion.

17. The electronic device of claim 16, wherein
the horizontal connection line includes the first connection portion and the second connection portion, and
the second connection portion at least partially overlaps the conductive line.

18. The electronic device of claim 17, wherein
the conductive line includes the first connection portion and the second connection portion, and
the second connection portion at least partially overlaps the horizontal connection line.

19. The electronic device of claim 17, wherein the second connection portion is on a layer at a level closer to the substrate than a level of the first connection portion.

20. The electronic device of claim 17, wherein a resistance of the first connection portion is less than a resistance of the second connection portion.
